(19) United States
(12) Patent Application Publication
(10) Pub. No.: US 2026/0182063 A1
(43) Pub. Date: Jun. 25, 2026

(54) IMAGE SENSOR

(71) Applicant: Samsung Electronics Co., Ltd., Suwon-si (KR)

(72) Inventors: Sooyoung KANG, Suwon-si (KR); Minsung KIM, Suwon-si (KR); Jameyung KIM, Suwon-si (KR); Dongmo IM, Suwon-si (KR); Chang Kyu LEE, Suwon-si (KR); Jihun LIM, Suwon-si (KR)

(73) Assignee: Samsung Electronics Co., Ltd., Suwon-si (KR)

(21) Appl. No.: 19/312,363

(22) Filed: Aug. 28, 2025

(30) Foreign Application Priority Data
Dec. 23, 2024 (KR) 10-2024-0194686

(51) Int. Cl. H10F 39/00

(52) U.S. Cl. CPC H10F 39/807; H10F 39/802; H10F 39/811

(57) ABSTRACT

An image sensor may include a semiconductor substrate, an isolation structure in the semiconductor substrate and defining first and second pixel regions, a transfer gate electrode on the first pixel region, a floating diffusion region in the first pixel region and at a side of the transfer gate electrode, a pixel gate electrode on the second pixel region, a source/drain region in the second pixel region and at a side of the pixel gate electrode, a connection conductive pattern on a first surface of the semiconductor substrate and connecting the floating diffusion region to the source/drain region, the connection conductive pattern including an edge portion adjacent to an outer side surface thereof, and a blocking pattern between the edge portion of the connection conductive pattern and the first surface of the semiconductor substrate.

### CROSS-REFERENCE TO RELATED APPLICATIONS

This U.S. non-provisional patent application claims priority under 35 U.S.C. § 119 to Korean Patent Application No. 10-2024-0194686, filed on Dec. 23, 2024, in the Korean Intellectual Property Office, the entire contents of which are hereby incorporated by reference.

### BACKGROUND

Some example embodiments relate to an image sensor, and in particular, to an image sensor with improved electrical and/or optical characteristics.

An image sensor is or includes a device that converts optical signals into electrical signals. With the recent development of the computer and communication industries, there is an increasing desire for high-performance image sensors to be used in a variety of applications such as one or more of digital cameras, camcorders, personal communication systems, gaming machines, security cameras, micro-cameras for medical applications, and/or robots.

### SUMMARY

Image sensors are generally classified into charge-coupled device (CCD) and complementary metal-oxide semiconductor (CMOS) image sensors. The CMOS image sensor can be operated in a simplified manner, and since signal-processing circuits of the CMOS image sensor can be integrated on a single chip, it may be possible to reduce a size of a product therewith. Alternatively or additionally, since the CMOS image sensor can be operated with a relatively low power consumption, it may be more easily applied to an electronic device with a limited battery capacity. Alternatively or additionally, since the CMOS image sensor can be fabricated using the existing CMOS fabrication techniques, it may be possible to reduce a manufacturing cost thereof. Alternatively or additionally, owing to an increase in resolution of CMOS image sensors, the use of CMOS image sensors is rapidly increasing.

Some example embodiments provide an image sensor with improved electrical and optical characteristics.

According to some example embodiments, an image sensor may include a semiconductor substrate, a PD isolation structure in the semiconductor substrate and defining first pixel regions and second pixel regions, a transfer gate electrode on the first pixel region, a floating diffusion region in the first pixel region and at a side of the transfer gate electrode, a pixel gate electrode on the second pixel region, a source/drain region in the second pixel region and at a side of the pixel gate electrode, a connection conductive pattern on a first surface of the semiconductor substrate and connecting the floating diffusion region to the source/drain region, the connection conductive pattern including an edge portion adjacent to an outer side surface of the connection conductive pattern, and a blocking pattern between the edge portion of the connection conductive pattern and the first surface of the semiconductor substrate.

Alternatively or additionally according to some example embodiments, an image sensor may include a semiconductor substrate, a PD isolation structure in the semiconductor substrate and first pixel regions and second pixel regions, a first photoelectric conversion element region and a second photoelectric conversion element in the first and second pixel regions, respectively, a first transfer gate electrode in the first pixel region and a first floating diffusion region at a side of the first transfer gate electrode, a second transfer gate electrode in the second pixel region and a second floating diffusion region at a side of the second transfer gate electrode, a plurality of pixel gate electrodes, which are respectively provided in the first pixel region and the second pixel region, and a plurality of source/drain regions, which are provided at first sides and second sides of each of the pixel gate electrodes, a connection conductive pattern connecting the first and second floating diffusion regions to a first source/drain region, which is one of the source/drain regions, the connection conductive pattern including a first connecting portion contacting the first floating diffusion region and the second floating diffusion region, and a second connecting portion extending from the first connecting portion and contacting the first source/drain region, and a blocking pattern between a bottom surface of an edge portion of the connection conductive pattern and a first surface of the semiconductor substrate.

According to some example embodiments, an image sensor may include a semiconductor substrate having a first surface and a second surface opposite to each other, a PD isolation structure in the semiconductor substrate and defining first pixel regions, second pixel regions, third pixel regions, and fourth pixel regions, a plurality of photoelectric conversion elements in the first to fourth pixel regions and in the semiconductor substrate, a device isolation layer adjacent to the first surface of the semiconductor substrate and defining first active portions and second active portions in each of the first to fourth pixel regions, a plurality of transfer gate electrodes on the first active portions in the first to fourth pixel regions, a plurality of floating diffusion regions in the first active portions and respectively in the first to fourth pixel regions, a plurality of pixel transistors on the second active portions and respectively in the first to fourth pixel regions, a connection conductive pattern on the first surface of the semiconductor substrate and contacting the floating diffusion regions in the first to fourth pixel regions and a first source/drain region of one of the pixel transistors, the connection conductive pattern including an edge portion adjacent to an outer side surface of the connection conductive pattern, and a pad portion contacting the floating diffusion region and the first source/drain region, a blocking pattern between the edge portion of the connection conductive pattern and the first surface of the semiconductor substrate, a plurality of color filters on the second surface of the semiconductor substrate to correspond to the pixel regions, a grid structure between the color filters and at least partly overlapping with the PD isolation structure, and a plurality of micro lenses on the plurality of color filters.

Alternatively or additionally according to some example embodiments, there is provided a method of fabricating an image sensor device comprising forming a photoelectric conversion element in a substrate, forming an isolation structure in the substrate, forming a transfer gate electrode on the substrate, the transfer gate electrode at least partly in the photoelectric conversion element, forming a first floating diffusion region in the substrate, conformally forming a spacer insulation layer on an upper surface of the substrate and on an upper surface of the transfer gate electrode, forming a first mask pattern on the spacer insulation layer and defining an opening over a portion of the first floating diffusion region, etching the spacer insulation layer exposed by the first mask pattern, forming a second floating diffusion pattern in the first floating diffusion pattern, conformally forming a conductive layer over the substrate and the spacer insulation layer, forming a second mask pattern over a portion of the conductive layer at least partly over the second floating diffusion region, and etching the spacer insulation pattern while leaving a remaining blocking pattern on a surface of the substrate and adjacent to the second floating diffusion region.

In some example embodiments, the transfer gate electrode may be formed in the substrate and may be formed in the photoelectric conversion element.

In some example embodiments, a depth of the second floating diffusion region may be less than a depth of the first floating diffusion region.

In some example embodiments, the forming the first floating diffusion region may include implanting dopants into the substrate at a first energy.

In some example embodiments, the forming the second floating diffusion region may include implanting dopants into the substrate at a second energy, less than the first energy.

### BRIEF DESCRIPTION OF THE DRAWINGS

FIG. 1 is a circuit diagram illustrating a unit pixel of a pixel array according to some example embodiments.

FIG. 2 is a plan view illustrating a unit pixel of an image sensor according to some example embodiments.

FIG. 3A is a sectional view, which is taken along a line A-A′ of FIG. 2 to illustrate an image sensor according to some example embodiments.

FIG. 3B is an enlarged sectional view illustrating a portion ‘P1’ of FIG. 3A.

FIG. 4A is a sectional view, which is taken along a line B-B′ of FIG. 2 to illustrate an image sensor according to some example embodiments.

FIG. 4B is an enlarged sectional view illustrating a portion ‘P2’ of FIG. 4A.

FIGS. 5A and 5C are sectional views, which are taken along a line C-C′ of FIG. 2 to illustrate an image sensor according to some example embodiments.

FIG. 5B is an enlarged sectional view illustrating a portion ‘P3’ of FIG. 5A.

FIGS. 6A, 6B, and 6C are sectional views, which are taken along a line D-D′ of FIG. to illustrate an image sensor according to some example embodiments.

FIGS. 7, 8, 9, 10, and 11 are plan views illustrating an image sensor according to some example embodiments.

FIGS. 12 to 19 are sectional views, which are taken along the line A-A′ of FIG. 2 to illustrate a method of fabricating an image sensor according to some example embodiments.

FIG. 20 is a plan view illustrating an image sensor according to some example embodiments.

FIG. 21 is a plan view schematically illustrating an image sensor according to some example embodiments.

FIGS. 22 and 23 are sectional views, which are taken along a line I-I′ of FIG. 21 to illustrate an image sensor according to some example embodiments.

### DETAILED DESCRIPTION

Some example embodiments will now be described more fully with reference to the accompanying drawings, in which example embodiments are shown.

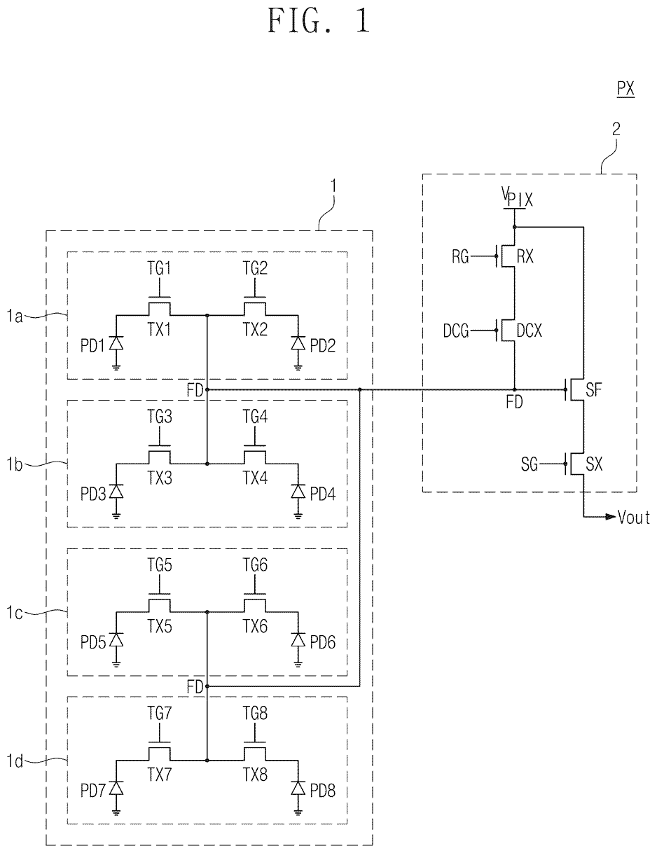

FIG. 1 is a circuit diagram illustrating a unit pixel of a pixel array according to some example embodiments.

Referring to FIG. 1, an image sensor may include a plurality of unit pixels, which are two-dimensionally arranged, e.g., arranged as a two-dimensional array, and each unit pixel PX may be configured to convert an optical signal to an electrical signal.

The unit pixel PX may include a photoelectric conversion circuit 1 and a pixel circuit 2.

The photoelectric conversion circuit 1 may include a plurality of photoelectric conversion groups 1a, 1b, 1c, and 1d. The photoelectric conversion circuit 1 may include at least 4, 8, or 16 photoelectric conversion groups 1a, 1b, 1c, and 1d. In some example embodiments, the number of photoelectric conversion groups is a power of two; however, example embodiments are not limited thereto. Each of the photoelectric conversion groups 1a, 1b, 1c, and 1d may include at least two photoelectric conversion devices (e.g., photodiodes), a plurality of transfer transistors, and a floating diffusion region. Each of the photoelectric conversion groups 1a, 1b, 1c, and 1d may include 4, 8, or 16 photoelectric conversion devices.

In some example embodiments, the photoelectric conversion circuit 1 may include the first, second, third, and fourth photoelectric conversion groups 1a, 1b, 1c, and 1d.

The first photoelectric conversion group 1a may include a first photodiode PD1, a second photodiode PD2, a first transfer transistor TX1, and a second transfer transistor TX2. The first and second transfer transistors TX1 and TX2 may be configured to transfer electric charges, which are accumulated in the first and second photoelectric conversion devices PD1 and PD2, to a floating diffusion region FD.

The second photoelectric conversion group 1b may include a third photodiode PD3, a fourth photodiode PD4, a third transfer transistor TX3, and a fourth transfer transistor TX4. The third and fourth transfer transistors TX3 and TX4 may be configured to transfer electric charges, which are accumulated in the third and fourth photoelectric conversion devices PD3 and PD4, to the floating diffusion region FD. The third photoelectric conversion group 1c may include a fifth photodiode PD5, a sixth photodiode PD6, a fifth transfer transistor TX5, and a sixth transfer transistor TX6. The fifth and sixth transfer transistors TX5 and TX6 may be configured to transfer electric charges, which are accumulated in the fifth and sixth photoelectric conversion devices PD5 and PD6, to the floating diffusion region FD. The fourth photoelectric conversion group 1d may include a seventh photodiode PD7, an eighth photodiode PD8, a seventh transfer transistor TX7, and an eighth transfer transistor TX8. The seventh and eighth transfer transistors TX7 and TX8 may be configured to transfer electric charges, which are accumulated in the seventh and eighth photoelectric conversion devices PD7 and PD8, to the floating diffusion region FD.

In some example embodiments, each of the first to eighth transfer transistors TX1 to TX8 may have the same electrical and/or physical properties; however, example embodiments are not limited thereto. Alternatively or additionally in some example embodiments, each of the photodiodes PD1 to PD8 may have the same electrical and/or physical characteristics; however, example embodiments are not limited thereto.

The first to fourth photoelectric conversion groups 1a, 1b, 1c, and 1d may be commonly connected to the floating diffusion region FD. For example, the first to eighth transfer transistors TX1 to TX8 may be commonly connected to the floating diffusion region FD.

Each of the first to fourth photoelectric conversion groups 1a, 1b, 1c, and 1d is illustrated to include two photodiodes, but example embodiments are not limited thereto. Each photoelectric conversion group may include 4 or 8 photodiodes, or more than 8 photodiodes.

Transfer gate electrodes of the first to eighth transfer transistors TX1 to TX8 may be controlled by first to eighth charge transfer signals TG1 to TG8. As described herein, the transfer gate electrode of each transfer transistor may have a dual vertical gate structure. The dual vertical gate structure may refer to a structure, in which two vertical transfer gates are provided to correspond to a single photodiode. The two vertical transfer gates in the dual vertical gate structure may be applied with the same transfer control signal.

The floating diffusion region FD may be configured to receive the electric charges, which are generated in at least one of the first to eighth photodiodes PD1 to PD8, and to cumulatively store the electric charges. A source follower transistor SF may be controlled by an amount of photocharges, which are accumulated in the floating diffusion region FD.

The pixel circuit 2 may include a reset transistor RX, the source follower transistor SF, a selection transistor SX, and a dual conversion gain transistor DCX. In some example embodiments, each of the unit pixels PX is illustrated to include four pixel transistors, but example embodiments are not limited thereto. The number of the pixel transistors in each unit pixel PX may be variously changed.

In detail, the reset transistor RX may reset, e.g., may periodically reset electric charges, which are accumulated in the floating diffusion region FD, by a reset signal RG applied to a reset gate electrode. In detail, the reset transistor RX may include a source terminal, which is connected to the dual conversion gain transistor DCX or the floating diffusion region FD, and a drain terminal, which is connected to a pixel power supply voltage VPIX. If the reset transistor RX and the dual conversion gain transistor DCX are turned on, the pixel power supply voltage VPIX may be transferred to the floating diffusion region FD. Thus, the electric charges, which are accumulated in the floating diffusion region FD, may be discharged to reset the floating diffusion region FD.

The dual conversion gain transistor DCX may be provided between and connected to the floating diffusion region FD and the reset transistor RX. The dual conversion gain transistor DCX may change a capacitance of the floating diffusion region FD in response to a dual conversion gain control signal DCG, thereby changing the conversion gain of the unit pixel PX.

In detail, during image capture, light of low brightness and high brightness may be incident into a pixel array, and the dual conversion gain transistor DCX may be turned on in a high brightness mode and may be turned off in a low brightness mode. Due to the dual conversion gain transistor DCX, it may be possible to realize different conversion gains in the high and low brightness modes.

If the dual conversion gain transistor DCX is turned on, the capacitance of the floating diffusion region FD may be increased and the conversion gain may be decreased, and if the dual conversion gain transistor DCX is turned off, the capacitance of the floating diffusion region FD may be decreased and the conversion gain may be increased.

The source follower transistor SF may be or may include, or be included in, a source follower buffer amplifier, which is configured to produce a source-drain current proportional to a charge amount of the floating diffusion region FD to be input to a source follower gate electrode. The source follower transistor SF may amplify a change in electric potential of the floating diffusion region FD and may output the amplified signal to an output line Vout through the selection transistor SX. The source follower transistor SF may include a drain terminal, which is connected to the pixel power supply voltage VPIX, and a source terminal, which is connected to a drain terminal of the selection transistor SX.

The selection transistor SX may be used to select a row of unit pixels P to be read out during a reading operation. When the selection transistor SX is turned on by a selection signal SG applied to a selection gate electrode, an electrical signal, which is output to a source electrode of the source follower transistor SF, may be output to the output line Vout.

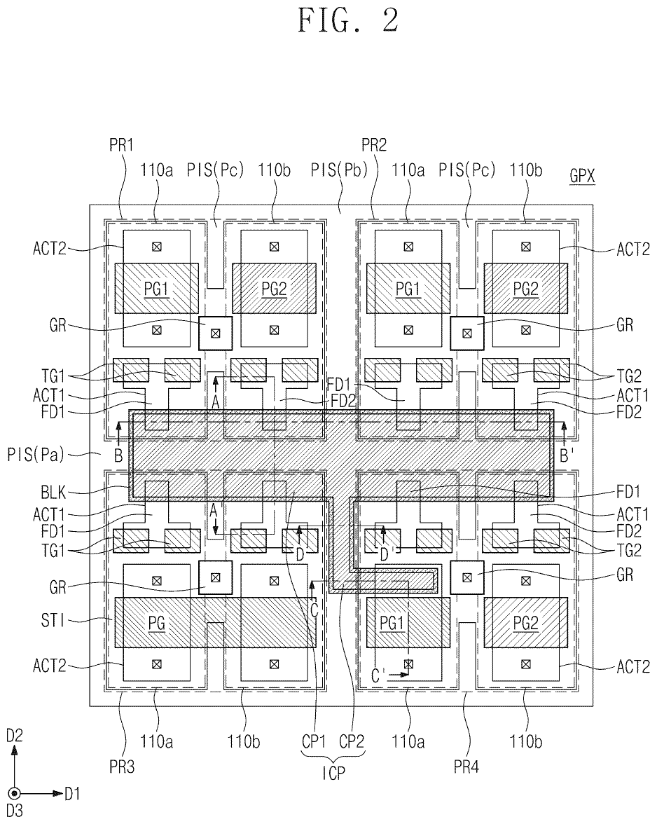

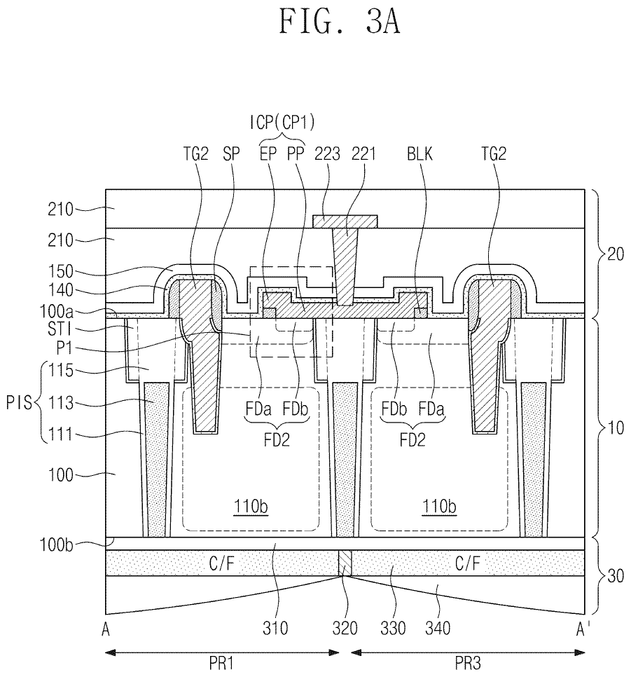

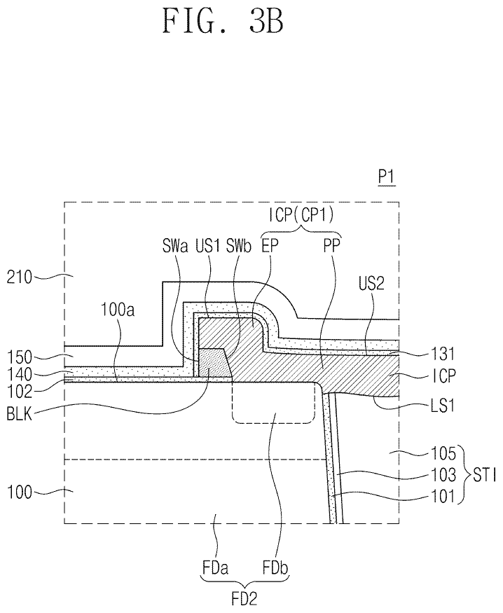

FIG. 2 is a plan view illustrating a unit pixel of an image sensor according to some example embodiments. FIGS. 3A, 4A, 5A, and 6A are sectional views, which are taken along lines A-A′, B-B′, C-C′, and D-D′, respectively, of FIG. 2 to illustrate an image sensor according to some example embodiments.

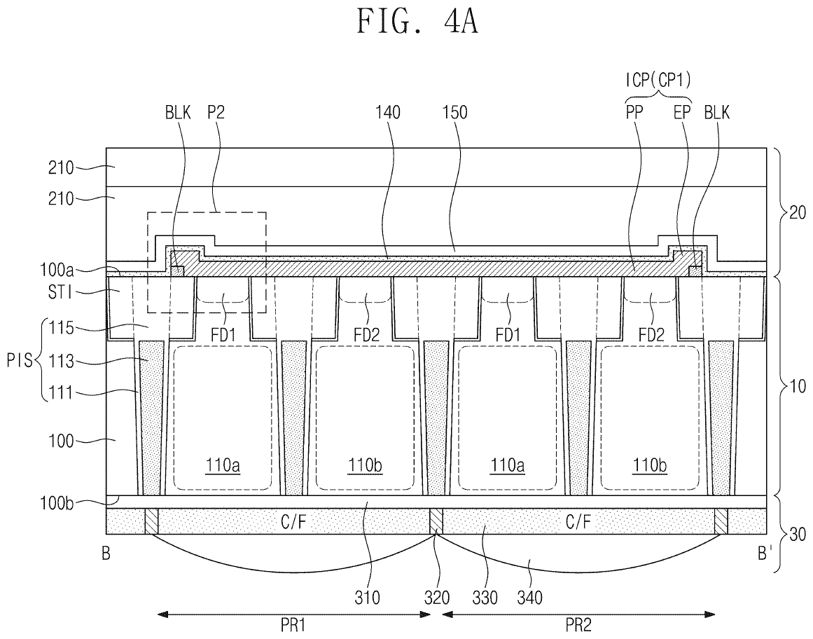

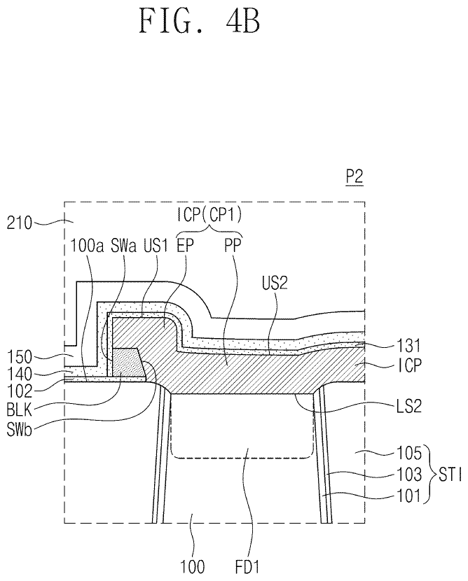

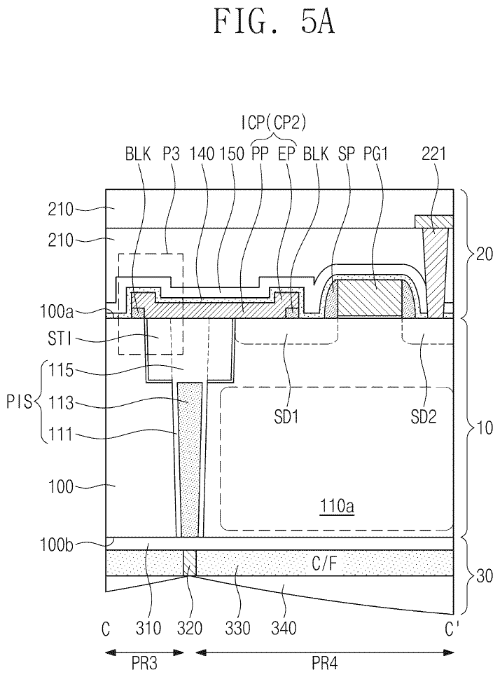

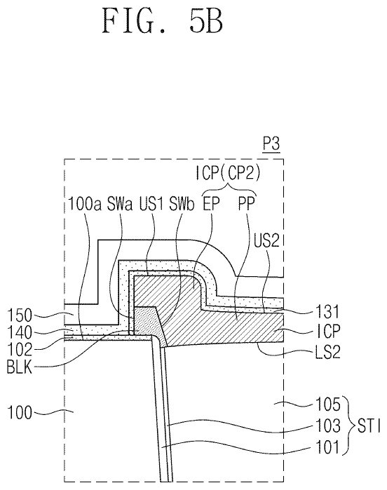

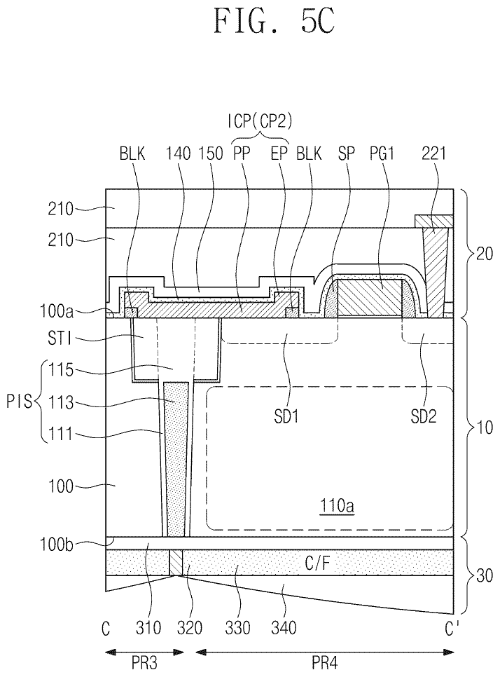

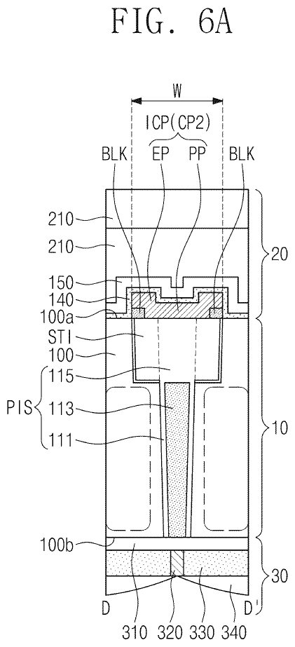

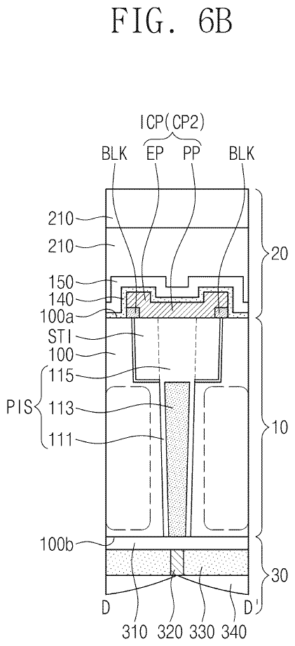

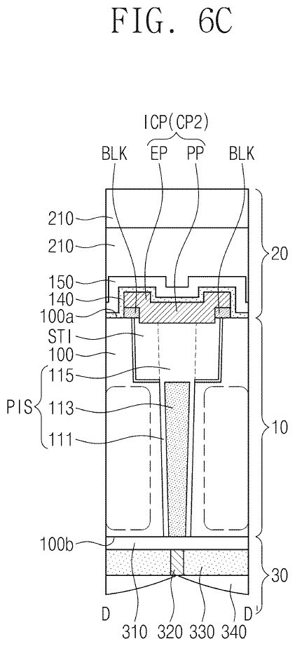

FIG. 3B is an enlarged sectional view illustrating a portion ‘P1’ of FIG. 3A. FIG. 4B is an enlarged sectional view illustrating a portion ‘P2’ of FIG. 4A. FIG. 5B is an enlarged sectional view illustrating a portion ‘P3’ of FIG. 5A. FIG. 5C is a sectional view taken along a line C-C′ of FIG. 2, and FIGS. 6B and 6C are sectional views taken along a line D-D′ of FIG. 2.

Referring to FIGS. 2, 3A, 4A, 5A, and 6A, an image sensor according to some example embodiments may include a photoelectric conversion circuit layer 10, a pixel circuit layer 20, and an optically-transparent layer 30.

The photoelectric conversion circuit layer 10 may be disposed between the pixel circuit layer 20 and the optically-transparent layer 30, when viewed in a vertical section. The photoelectric conversion circuit layer 10 may include a semiconductor substrate 100, a PD isolation structure PIS, a device isolation layer STI, photoelectric conversion elements 110a, 110b, 110c, and 110d, transfer gate electrodes TG1, TG2, TG3, and TG4, and floating diffusion regions FD1 and FD2.

The pixel circuit layer 20 may include pixel circuits (e.g., MOS transistors such as NMOS and/or PMOS transistors), which are electrically connected to the floating diffusion regions FD1 and FD2. For example, the pixel circuit layer 20 may include the reset transistor RX, the selection transistor SX, the dual conversion gain transistor DCX, and the source follower transistor SF, which were described with reference to FIG. 1, and interconnection lines, which are connected to the pixel circuits 2 of FIG. 1.

In detail, the semiconductor substrate 100 may have a first or front surface 100a and a second or rear surface 100b, which are opposite to each other. The semiconductor substrate 100 may be or may include a substrate including a bulk silicon substrate and an epitaxial layer, which are sequentially stacked and are of a first conductivity type (e.g., p-type), and in the case where the bulk silicon substrate is removed during a process of fabricating the image sensor, the semiconductor substrate 100 may be composed of only the p-type epitaxial layer. In some example embodiments, the semiconductor substrate 100 may be or include a bulk semiconductor substrate including a well of the first conductivity type.

The semiconductor substrate 100 may include a plurality of pixel regions PR1, PR2, PR3, and PR4 defined by the PD isolation structure PIS. The pixel regions PR1, PR2, PR3, and PR4 may be arranged in a first direction D1 and a second direction D2, which are not parallel to each other, or in a matrix shape.

The pixel regions may include first, second, third, and fourth pixel regions PR1, PR2, PR3, and PR4, the first and second pixel regions PR1 and PR2 may be disposed adjacent to each other in the first direction D1, and the first and third pixel regions PR1 and PR3 may be disposed adjacent to each other in the second direction D2. The second and fourth pixel regions PR2 and PR4 may be adjacent to each other in the second direction D2, and the second and third pixel regions PR2 and PR3 may be arranged in a diagonal direction. Here, the first and second directions D1 and D2 may be parallel to the first surface 100a of the semiconductor substrate 100 and may not be parallel to each other, e.g., may intersect at an angle such as a 90 degree angle. A third direction D3 may be perpendicular to the first surface 100 a of the semiconductor substrate 100.

The first to fourth pixel regions PR1 to PR4 may constitute a single pixel group GPX. In some example embodiments, each pixel group GPX is illustrated to include four pixel regions, but example embodiments are not limited thereto. For example, the pixel group GPX may be composed of 6, 8, 9, or 16 pixel regions.

Each of the first to fourth pixel regions PR1 to PR4 may be enclosed by the PD isolation structure PIS, when viewed in a plan view. Each of the first to fourth pixel regions PR1 to PR4 may be defined by a pair of first portions Pa, which extend in the first direction D1, and a pair of second portions Pb, which extend in the second direction D2. In some example embodiments, the PD isolation structure PIS may include a pair of third portions Pc, in each of the first to fourth pixel regions PR1 to PR4. The third portions Pc may be extended from the first portions Pa in the second direction D2 or from the second portions Pb in the first direction D1 and may be spaced apart from each other.

In some example embodiments, the PD isolation structure PIS may be provided to penetrate the semiconductor substrate 100. In detail, the PD isolation structure PIS may have a length in a direction (e.g., the third direction D3), which is perpendicular to the top surface of the semiconductor substrate 100, and the length of the PD isolation structure PIS may be substantially equal to a vertical thickness of the semiconductor substrate 100. In some example embodiments, the PD isolation structure PIS may be vertically extended from the first surface 100a of the semiconductor substrate 100 toward the second surface 100b and may be spaced apart from the second surface 100b of the semiconductor substrate 100.

In some example embodiments, the PD isolation structure PIS may include a liner insulating pattern 111, a gapfill pattern 113, and a capping insulating pattern 115. The gapfill pattern 113 may be provided to vertically penetrate a portion of the semiconductor substrate 100, and the liner insulating pattern 111 may be provided between the gapfill pattern 113 and the semiconductor substrate 100. The capping insulating pattern 115 may be disposed on the gapfill pattern 113. The liner insulating pattern 111 and the capping insulating pattern 115 may be formed of or include at least one of silicon oxide, silicon oxynitride, or silicon nitride. The gapfill pattern 113 may include an undoped poly-silicon layer and/or a doped poly-silicon layer. The gapfill pattern 113 may include an air gap or may define a avoid. The capping insulating pattern 115 of the PD isolation structure PIS may be formed of or include the same insulating material as the device isolation layer STI, and in this case, there may be no visible or observable boundary or interface between the capping insulating pattern 115 and the device isolation layer STI.

In some example embodiments, in each of the first to fourth pixel regions PR1 to PR4, the first and second photoelectric conversion elements 110a and 110b may be provided in the semiconductor substrate 100. Light, which is incident from the outside, may be converted to electrical signals, in the first and second photoelectric conversion elements 110a and 110b.

The first and second photoelectric conversion elements 110a and 110b may be impurity regions, which are doped with impurities to have a second conductivity type (e.g., n-type) different from the first conductivity type of the semiconductor substrate 100. In some example embodiments, the first and second photoelectric conversion elements 110a and 110b may be counterdoped with impurities of the first conductivity type at a much lower concentration than that of the second conductivity type; example embodiments are not limited thereto. The semiconductor substrate 100 of the first conductivity type and the first and second photoelectric conversion elements 110a and 110b may constitute a pair of photodiodes. For example, a junction serving as a photodiode may be formed by the semiconductor substrate 100 of the first conductivity type and the first or second photoelectric conversion element 110a or 110b. In the case where light is incident into the first and second photoelectric conversion elements 110a and 110b constituting the photodiode, photocharges may be generated and accumulated in proportion to an intensity of the incident light.

In each of the first to fourth pixel regions PR1 to PR4, electrical signals, which are output from the first and second photoelectric conversion elements 110a and 110b, may have a phase difference and in some cases may be digital signals and/or analog signals. The image sensor may be configured to measure a distance to a target object, based on a difference in phase between the electrical signals, which are output from the paired photoelectric conversion elements (e.g., the first and second photoelectric conversion elements 110a and 110b), to examine whether the target object is in focus or a degree to which it is out of focus, and to correct, e.g., to automatically correct the focus of the image sensor based the examined result.

Each of the first and second photoelectric conversion elements 110a and 110b may have a first width in the first direction D1 and a first length, which is larger than the first width, in the second direction D2. In some example embodiments, the first length may be about 2 times the first width.

The first and second photoelectric conversion elements 110a and 110b may be spaced apart from each other in the first direction D1, with the third portions Pc of the PD isolation structure PIS interposed therebetween. The third portions Pc of the PD isolation structure PIS may be configured to physically reflect the incident light at an edge portion of each of the first to fourth pixel regions PR1 to PR4, and thus, it may be possible to reduce a cross-talk issue between the first and second photoelectric conversion elements 110a and 110b.

The device isolation layer STI may be disposed to be adjacent to the first surface 100a of the semiconductor substrate 100, in each of the first to fourth pixel regions PR1 to PR4. A bottom surface of the device isolation layer STI may be spaced apart from the first and second photoelectric conversion elements 110a and 110b.

In some example embodiments, the device isolation layer STI may define first and second active portions ACT1 and ACT2, in each of the first to fourth pixel regions PR1 to PR4. The first and second active portions ACT1 and ACT2 may be portions of the semiconductor substrate 100. When viewed in a plan view, the first and second active portions ACT1 and ACT2 may be overlapped with one of the first and second photoelectric conversion elements 110a and 110b. For example, a pair of the first active portions ACT1 and a pair of the second active portions ACT2 may be provided in each of the pixel regions PR1 to PR4, but example embodiments are not limited thereto.

The first and second active portions ACT1 and ACT2 may be spaced apart from each other in the second direction D2 by the device isolation layer STI and may have different sizes and shapes from each other. The first active portion ACT1 may have the shape of a letter ‘T’, but example embodiments are not limited thereto; for example, the first active portion ACT1 may have various polygonal shapes (e.g., rectangular and/or tetragonal shapes). The second active portion ACT2 may have a long axis in the second direction D2 and a short axis in the first direction D1. Each of the second active portion ACT2 may have a second length, which is smaller than a first length of the first or second photoelectric conversion element 110a or 110b, when measured in the second direction D2.

The first and second active portions ACT1 and ACT2 of the third and fourth pixel regions PR3 and PR4 and the first and second active portions ACT1 and ACT2 of the first and second pixel regions PR1 and PR2 may be disposed in a mirror symmetric manner, e.g., around an axis of symmetry running in the first direction D1.

The device isolation layer STI may be provided in a trench, which is formed by recessing the first surface 100a of the semiconductor substrate 100. The device isolation layer STI may be formed of an insulating material.

As an example, referring to FIGS. 3B, 4B, and 5B, the device isolation layer STI may include a liner oxide layer 101 and a liner nitride layer 103, which are formed to conformally cover a surface of the trench, and a gapfill oxide layer 105 filling the trench, which is covered provided with the liner oxide layer 101 and the liner nitride layer 103. The gapfill oxide layer 105 may include at least one of, for example, a silicon oxide layer, a silicon oxynitride layer, and a silicon nitride layer.

The first and second transfer gate electrodes TG1 and TG2 may be disposed in each of the first to fourth pixel regions PR1 to PR4. Each of the first and second transfer gate electrodes TG1 and TG2 may be disposed on the first active portion ACT1. The first and second transfer gate electrodes TG1 and TG2 may include portions, which are disposed in the trench formed by recessing the first surface 100a of the semiconductor substrate 100. A gate insulating layer may be interposed between the first and second transfer gate electrodes TG1 and TG2 and the semiconductor substrate 100. Insulating spacers SP may be disposed on opposite side surfaces of each of the first and second transfer gate electrodes TG1 and TG2.

In some example embodiments, each of the first and second transfer gate electrodes TG1 and TG2 may have a dual vertical gate electrode structure, in which two vertical portions are extended into the semiconductor substrate 100. In some example embodiments, the shapes and positions of the first and second transfer gate electrodes TG1 and TG2 may be variously changed.

In each of the first to fourth pixel regions PR1 to PR4, the first floating diffusion region FD1 may be provided in a portion of the first active portion ACT1 near the first transfer gate electrode TG1. The second floating diffusion region FD2 may be provided in a portion of the first active portion ACT1 near the second transfer gate electrode TG2.

The first and second floating diffusion regions FD1 and FD2 may be formed by doping, e.g., implanting the semiconductor substrate 100 with dopants of the second conductivity type, which is different from that of the semiconductor substrate 100. For example, the first and second floating diffusion regions FD1 and FD2 may be n-type doping regions. In some example embodiments, an implantation energy of dopants implanted into the first floating diffusion region FD1 may be less than an implantation energy of dopants implanted into the second floating diffusion region FD2.

Each of the first and second floating diffusion regions FD1 and FD2 may include a first doped region FDa and a second doped region FDb in the first doped region FDa, and a doping concentration in the second doped region FDb may be higher than a doping concentration in the first doped region FDa.

In each of the first, second, and fourth pixel regions PR1, PR2, and PR4, first and second pixel gate electrodes PG1 and PG2 may be disposed on the second active portions ACT2, respectively. In each the first, second, and fourth pixel regions PR1, PR2, and PR4, the first pixel gate electrode PG1 may overlap with or at least partly overlap with the first photoelectric conversion element 110a, and the second pixel gate electrode PG2 may overlap with or at least partly overlap with the second photoelectric conversion element 110b.

In the third pixel region PR3, a pixel gate electrode PG may be disposed on the second active portions ACT2. In the third pixel region PR3, the pixel gate electrode PG may be longer than the first and second pixel gate electrodes PG1 and PG2 in the first direction D1. For example, the pixel gate electrode PG may cross the second active portions ACT2 in the third pixel region PR3. The pixel gate electrode PG may overlap with or at least partly overlap with portions of the first and second photoelectric conversion elements 110a and 110b in the third pixel region PR3.

First source/drain regions SD1 may be provided in the second active portions ACT2 and at a side of the first and second pixel gate electrodes PG1 and PG2 and the pixel gate electrode PG, and second source/drain regions SD2 may be provided in the second active portions ACT2 and at an opposite side of the first and second pixel gate electrodes PG1 and PG2 and the pixel gate electrode PG.

In each of the first to fourth pixel regions PR1 to PR4, the first and second pixel gate electrodes PG1 and PG2 and the pixel gate electrode PG may constitute the pixel transistors (e.g., the reset, source follower, dual conversion gain, and selection transistors RX, SF, DCX, and SX) previously described with reference to FIG. 1.

In some example embodiments, the first pixel gate electrode PG1 in the first pixel region PR1 may be provided as the selection gate electrode described with reference to FIG. 1, and the pixel gate electrode PG in the third pixel region PR3 may be provided as the source follower gate electrode described with reference to FIG. 1. The first pixel gate electrode PG1 in the fourth pixel region PR4 may be provided as the dual conversion gate electrode described with reference to FIG. 1. The second pixel gate electrode PG2 in the fourth pixel region PR4 may be provided as the reset gate electrode described with reference to FIG. 1. The functions of the first and second pixel gate electrodes PG1 and PG2 in the first to fourth pixel regions PR1 to PR4 may be variously changed.

The insulating spacers SP may be disposed on opposite side surfaces of the first and second pixel gate electrodes PG1 and PG2.

Furthermore, in each of the first to fourth pixel regions PR1 to PR4, a ground impurity region GR may be provided between the first and second photoelectric conversion elements 110a and 110b. The ground impurity region GR may be provided between the third portions Pc of the PD isolation structure PIS. The ground impurity region GR may be formed by a process of injecting, e.g., implanting dopants of the same first conductivity type as the semiconductor substrate 100.

In some example embodiments, a connection conductive pattern ICP may be disposed on the first surface 100a of the semiconductor substrate 100 and may be commonly connected to the first and second floating diffusion regions FD1 and FD2 provided in the first to fourth pixel regions PR1 to PR4. In some example embodiments, the connection conductive pattern ICP may be connected to the first source/drain regions SD1 of the pixel transistors, which are provided in at least two of the first to fourth pixel regions PR1 to PR4. In some example embodiments, the connection conductive pattern ICP may be connected to the first source/drain region SD1, which is provided at a side of the first pixel gate electrode PG1 in the fourth pixel region PR4. For example, the connection conductive pattern ICP may electrically connect the dual conversion gain transistor DCX of FIG. 1 to both of the first and second floating diffusion regions FD1 and FD2.

The connection conductive pattern ICP may be formed of a conductive material. The connection conductive pattern ICP may be formed of single-crystalline silicon and/or poly-crystalline silicon that is doped with or that otherwise incorporates dopants of the second conductivity type. In addition, the connection conductive pattern ICP may be formed of or include at least one of metallic materials (e.g., one or more of tungsten, titanium, tantalum, and cobalt). A concentration of the second conductivity type dopants in the connection conductive pattern ICP may be higher than, e.g., several orders of magnitude higher than, a doping concentration in the second doped regions FDb of the first and second floating diffusion regions FD1 and FD2.

The connection conductive pattern ICP may have a first thickness on the first surface 100a of the semiconductor substrate 100, and each of the first and second pixel gate electrodes PG1 and PG2 may have a second thickness on the first surface 100a of the semiconductor substrate 100. Here, the second thickness may be larger than the first thickness.

In detail, the connection conductive pattern ICP may include an edge portion EP, which is adjacent to an outer side surface thereof, and a pad portion PP, which is in contact with the first and second floating diffusion regions FD1 and FD2 and the first source/drain region SD1. In some example embodiments, the connection conductive pattern ICP may include a first connecting portion CP1, which is in contact with the first and second floating diffusion regions FD1 and FD2, and a second connecting portion CP2, which is extended from the first connecting portion CP1 and is in contact with the first source/drain region SD1, when viewed in a plan view.

The first connecting portion CP1 may be in contact with, e.g., may be in direct contact with the second doped regions FDb of the first and second floating diffusion regions FD1 and FD2 in the first to fourth pixel regions PR1 to PR4. The second connecting portion CP2 may have the smallest width smaller than the smallest width of the first connecting portion CP1 and may be in direct contact with at least one of the first source/drain regions SD1.

Referring to FIG. 6A, the smallest width of the second connecting portion CP2 may be substantially equal to a width W of the device isolation layer STI. Referring to FIG. 6B, the smallest width of the second connecting portion CP2 may be larger than a width of the device isolation layer STI. Referring to FIG. 6C, the pad portion PP of the connection conductive pattern ICP may be partially inserted into the device isolation layer STI.

In some example embodiments, when viewed in a plan view, the connection conductive pattern ICP may have various shapes, depending on the arrangement of the pixel transistors.

Referring to FIGS. 3B, 4B, and 5B, the connection conductive pattern ICP may have a first top surface US1 in the edge portion EP and a second top surface US2 in the pad portion PP. Here, the first top surface US1 may be placed at a level higher than the second top surface US2, when measured from the first surface 100a of the semiconductor substrate 100. The edge portion EP of the connection conductive pattern ICP may be placed on the first and second active portions ACT1 and ACT2 or on the device isolation layer STI and the PD isolation structure PIS, depending on the position.

The connection conductive pattern ICP may have a first bottom surface LS1, which is in contact with the device isolation layer STI, and a second bottom surface LS2, which is in contact with the first and second floating diffusion regions FD1 and FD2 and the first source/drain region SD1.

The first bottom surface LS1 of the connection conductive pattern ICP may be located at a level lower than the first surface 100a of the semiconductor substrate 100. The second bottom surface LS2 of the connection conductive pattern ICP may be located at a level lower than a top surface of the device isolation layer STI.

In some example embodiments, a blocking pattern BLK may be disposed between the edge portion EP of the connection conductive pattern ICP and the semiconductor substrate 100, the device isolation layer STI, or the PD isolation structure PIS.

The blocking pattern BLK may overlap with or at least partly overlap with the edge portion EP of the connection conductive pattern ICP, when viewed in a plan view. For example, the blocking pattern BLK may be disposed along an outer side surface of the connection conductive pattern ICP.

The blocking pattern BLK may include the same insulating material as the insulating spacers SP, which are disposed on opposite side surfaces of the first and second transfer gate electrodes TG1 and TG2 and opposite side surfaces of the first and second pixel gate electrodes PG1 and PG2. The blocking pattern BLK may be formed of or include at least one of, for example, silicon oxide, silicon nitride, and/or silicon oxynitride. The blocking pattern BLK may prevent or reduce the likelihood of and/or the impact from the edge portion EP of the connection conductive pattern ICP being in contact with the first and second active portions ACT1 and ACT2.

Referring to FIGS. 3B, 4B, and 5B, a bottom surface of the blocking pattern BLK may be located at a level higher than a bottom surface of the pad portion PP of the connection conductive pattern ICP. The blocking pattern BLK may have an outer side surface SWa, which is adjacent to the outer side surface of the connection conductive pattern ICP, and an inner side surface SWb, which is opposite to the outer side surface SWa. The outer side surface SWa of the blocking pattern BLK may be vertically aligned to the outer side surface of the connection conductive pattern ICP. The inner side surface SWb of the blocking pattern BLK may be inclined at a specific angle to the first surface 100a of the semiconductor substrate 100. The inner side surface SWb of the blocking pattern BLK may be in direct contact with the connection conductive pattern ICP.

Referring to FIG. 6A, the blocking pattern BLK may be disposed between the second connecting portion CP2 of the connection conductive pattern ICP and the device isolation layer STI. Referring to FIGS. 5C and 6B, the blocking pattern BLK may be placed on a boundary between the semiconductor substrate 100 and the device isolation layer STI.

First and second etch stop layers 140 and 150 may be sequentially formed on the first surface 100a of the semiconductor substrate 100. The first and second etch stop layers 140 and 150 may cover the first and second transfer gate electrodes TG1 and TG2, the first and second pixel gate electrodes PG1 and PG2, the pixel gate electrode PG, and the connection conductive pattern ICP with a uniform thickness. The first and second etch stop layers 140 and 150 may be formed of or include silicon nitride. The second etch stop layer 150 may be thicker than the first etch stop layer 140.

Referring to FIGS. 3B, 4B, and 5B, the first etch stop layer 140 may cover the outer side surface SWa of the blocking pattern BLK and the outer side surface of the connection conductive pattern ICP with a uniform thickness.

A surface insulating layer 102 may be disposed on the first surface 100a of the semiconductor substrate 100, and a portion of the surface insulating layer 102 may be disposed between the first surface 100a of the semiconductor substrate 100 and the bottom surface of the blocking pattern BLK. The surface insulating layer 102 may be formed of or include at least one of, for example, silicon oxide and/or silicon oxynitride.

A capping insulating layer 131 may be provided to conformally cover the connection conductive pattern ICP. The capping insulating layer 131 may be in contact with the outer side surface of the connection conductive pattern ICP and the outer side surface of the blocking pattern BLK. The capping insulating layer 131 may be formed of or include at least one of, for example, silicon oxide and/or silicon oxynitride.

Interlayer insulating layers 210 may be stacked on the first surface 100a of the semiconductor substrate 100 to cover the pixel transistors RX, SF, DCX, and SEL constituting the pixel circuits 2 of FIG. 1 and the first and second transfer gate electrodes TG1 and TG2. The interlayered insulating layers 210 may be formed of or include at least one of, for example, silicon oxide, silicon nitride, or silicon oxynitride.

Contact plugs 221, which are connected to the pixel circuits 2 of FIG. 1, and interconnection lines 223, which are connected to the contact plugs 221, may be disposed in the interlayer insulating layers 210. One of the contact plugs 221 may be provided to penetrate the interlayer insulating layer 210 and the first and second etch stop layers 140 and 150 and may be coupled to the connection conductive pattern ICP.

Referring to FIGS. 3A, 4A, 5A, and 6A, the optically-transparent layer 30 may be disposed on the second surface 100b of the semiconductor substrate 100. The optically-transparent layer 30 may include a planarization insulating layer 310, a grid structure 320, color filters 330, and micro lenses 340. The optically-transparent layer 30 may be configured to perform an operation of focusing and filtering light, which is incident from the outside, and to provide the light to the photoelectric conversion circuit layer 10.

The planarization insulating layer 310 may cover the second surface 100b of the semiconductor substrate 100. The planarization insulating layer 310 may be formed of a transparent insulating material and may include a plurality of layers. The planarization insulating layer 310 may be formed of an insulating material whose refractive index is different from (e.g., greater than or less than) the semiconductor substrate 100. The planarization insulating layer 310 may include at least one of metal oxide and/or silicon oxide.

The grid structure 320 may be disposed on the planarization insulating layer 310. When viewed in a plan view, the grid structure 320 may have a lattice shape, similar to the PD isolation structure PIS. The grid structure 320 may be overlapped with the PD isolation structure PIS, when viewed in a plan view. That is, the grid structure 320 may include first portions, which are extended in the first direction D1, and second portions, which are extended in the second direction D2 to cross the first portions. A width of the grid structure 320 may be substantially equal to or smaller than the smallest width of the PD isolation structure PIS.

The grid structure 320 may include a conductive pattern and/or a low-refractive pattern. The conductive pattern may be formed of or include at least one of metallic materials (e.g., one or more of titanium, tantalum, and tungsten). The low-refractive pattern may be formed of a material whose refractive index is lower than the conductive pattern. The low-refractive pattern may be formed of an organic material and may have a refractive index of about 1.1 to 1.3. For example, the grid structure 320 may be or may include a polymer layer containing silica nano particles.

The color filter 330 may be formed to correspond to a pixel region PR. The color filters 330 may be provided to fill a space defined by the grid structure 320. The color filters 330 may include red, green, or blue color filters or magenta, cyan, or yellow color filters, which are determined based on positions of the unit pixels. In some example embodiments, at least one of the color filters 330 may include a white color filter or an infrared filter. In some example embodiments, the color filters 330 may be arranged in a Bayer pattern; example embodiments are not limited thereto.

The micro lenses 340 may be disposed on the color filters 330. The micro lenses 340 may have a convex shape and may have a specific curvature radius. The micro lenses 340 may be formed of an optically transparent resin. The micro lenses 340 may be disposed on the color filters 330 to correspond to the pixel regions PR, respectively. In some example embodiments, at least one of the micro lenses 340 may be commonly disposed on at least two pixel regions PR.

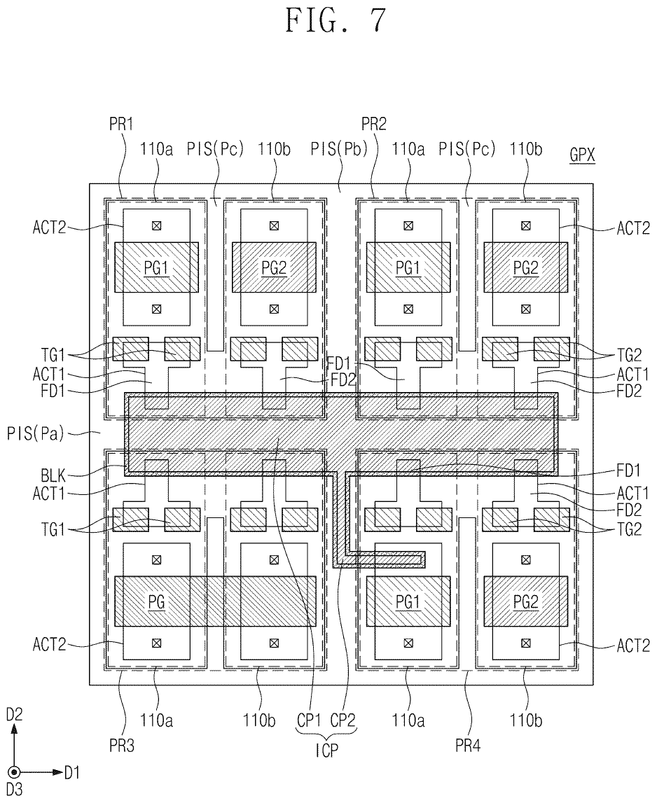

FIGS. 7, 8, 9, 10, and 11 are plan views illustrating an image sensor according to some example embodiments. For concise description, the same technical features as the image sensor described with reference to FIGS. 3A, 4A, 5A, and 6A may be omitted from the following description, and different technical features will be described below.

Referring to FIG. 7, the PD isolation structure PIS may include a pair of first portions Pa and a pair of second portions Pb defining the first to fourth pixel regions PR1 to PR4. In addition, in each of the first to fourth pixel regions PR1 to PR4, the PD isolation structure PIS may further include the third portion Pc extended toward the center thereof. The third portion Pc may be extended from one of the first portions Pa in the second direction D2.

The third portion Pc of the PD isolation structure PIS may be placed between the first and second photoelectric conversion elements 110a and 110b, in each of the first to fourth pixel regions PR1 to PR4. The third portion Pc may be disposed between the second active portions ACT2.

The connection conductive pattern ICP may be spaced apart from the third portion Pc of the PD isolation structure PIS, when viewed in a plan view.

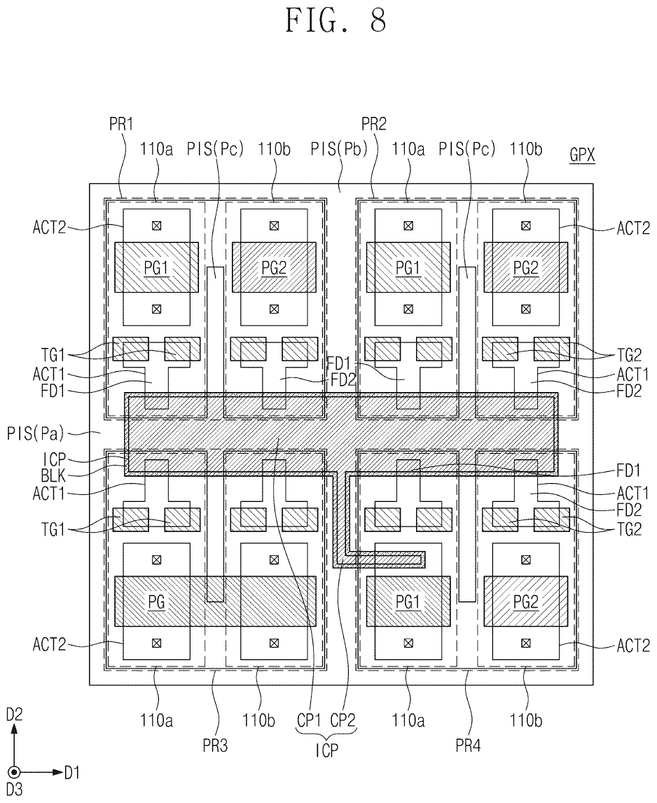

Referring to FIG. 8, in each of the first to fourth pixel regions PR1 to PR4, the PD isolation structure PIS may include the third portion Pc, which is extended from one of the first portions Pa in the second direction D2, as described above. Here, the third portion Pc may be disposed between the first active portions ACT1, and a portion of the third portion Pc may be overlapped with the connection conductive pattern ICP.

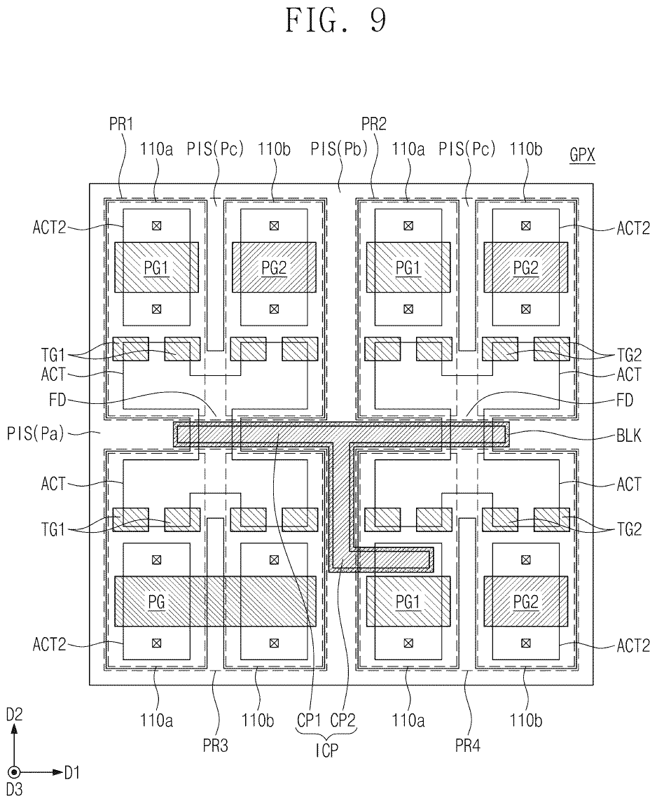

Referring to FIG. 9, in each of the first to fourth pixel regions PR1 to PR4, the PD isolation structure PIS may include the third portion Pc, which is extended from one of the first portions Pa in the second direction D2, as described above. Here, the third portion Pc may be disposed between the second active portions ACT2, and the first active portions described with reference to FIG. 2 may be connected to each other to form a common active portion ACT.

In addition, the common active portion ACT in the first pixel region PR1 may be connected to the common active portion ACT in the third pixel region PR3. Portions of the PD isolation structure PIS between the first and third pixel regions PR1 and PR3 may be spaced apart from each other. Similarly, the common active portion ACT in the second pixel region PR2 may be connected to the common active portion ACT in the fourth pixel region PR4. Portions of the PD isolation structure PIS between the second and fourth pixel regions PR2 and PR4 may be spaced apart from each other.

The floating diffusion region FD1 or FD2 may be provided in an open region, in which the PD isolation structure PIS is omitted between the first and third pixel regions PR1 and PR3.

The first connecting portion CP1 of the connection conductive pattern ICP may connect the floating diffusion region FD between the first and third pixel regions PR1 and PR3 to the floating diffusion region FD between the second and fourth pixel regions PR2 and PR4, and the second connecting portion CP2 of the connection conductive pattern ICP may be extended from the first connecting portion CP1 and may be connected to one of the first source/drain regions SD1.

The connection conductive pattern ICP may include the edge portion EP, which is adjacent to an outer side surface thereof, and the blocking pattern BLK may be disposed between the edge portion EP and the first surface 100a of the semiconductor substrate 100. For example, the blocking pattern BLK may be overlapped with the edge portion EP of the connection conductive pattern ICP, when viewed in a plan view, as described above.

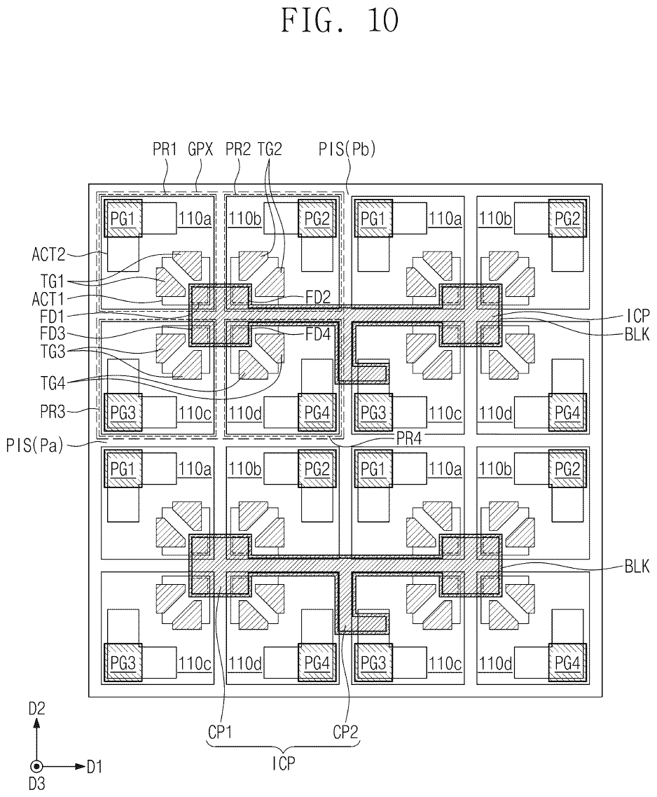

Referring to FIG. 10, the semiconductor substrate 100 may include a plurality of pixel groups GPX. Each of the pixel groups GPX may include at least 4, 8, or 16 pixel regions PR. In each pixel group GPX, the pixel regions PR may be arranged in the first and second directions D1 and D2, which are not parallel to each other, or in a matrix shape.

The first to fourth photoelectric conversion elements 110a to 110d may be provided in the first to fourth pixel regions PR1 to PR4, respectively.

The first and second active portions ACT1 and ACT2 may be provided in each of the first to fourth pixel regions PR1 to PR4 by the device isolation layer STI, which is formed in the semiconductor substrate 100 near the first surface 100a. The first and second active portions ACT1 and ACT2 may be defined by the device isolation layer STI adjacent to the first surface 100a of the semiconductor substrate 100.

The first to fourth transfer gate electrodes TG1, TG2, TG3, and TG4 may be provided in the first to fourth pixel regions PR1 to PR4, respectively. Each of the first to fourth transfer gate electrodes TG1, TG2, TG3, and TG4 may have a dual vertical gate electrode structure, which includes two vertical portions extended into the semiconductor substrate 100, as described above.

In each of the first to fourth pixel regions PR1 to PR4, the pixel transistor may be provided on the second active portion ACT2.

First to fourth floating diffusion regions FD1 to FD4 may be respectively provided in portions of the first active portions ACT1 at first sides of the first to fourth transfer gate electrodes TG1, TG2, TG3, and TG4. The first to fourth floating diffusion regions FD1 to FD4 may be disposed to be adjacent to each other and may be disposed on a center portion of each of the pixel groups GPX.

The first connecting portion CP1 of the connection conductive pattern ICP may be connected to the first to fourth floating diffusion regions FD1 to FD4 of adjacent ones of the pixel groups. The second connecting portion of the connection conductive pattern ICP may be extended from the first connecting portion CP1 and may be connected to one of the first source/drain regions SD1.

The connection conductive pattern ICP may include the edge portion, which is adjacent to an outer side surface thereof, as described above and the blocking pattern BLK may be disposed between the edge portion and the first surface 100a of the semiconductor substrate 100. For example, the blocking pattern BLK may be overlapped with the edge portion of the connection conductive pattern ICP, when viewed in a plan view, as described above.

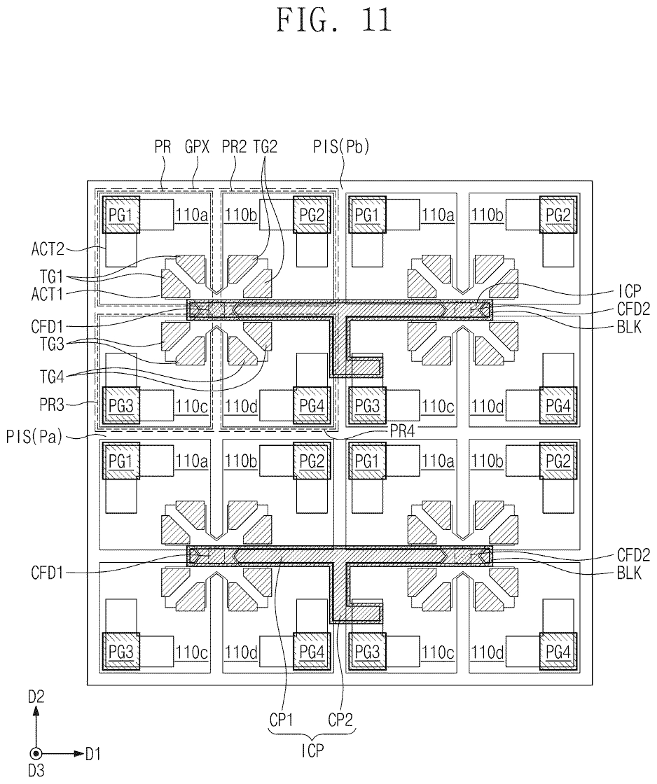

Referring to FIG. 11, the common active portion ACT may be commonly provided in the first to fourth pixel regions PR1 to PR4, and the second active portion ACT2 may be provided in each of the first to fourth pixel regions PR1 to PR4.

The first to fourth transfer gate electrodes TG1 to TG4 may be provided on the common active portion ACT.

In each pixel group GPX, a common floating diffusion region CFD1 or CFD2 may be provided in the common active portion ACT. In some example embodiments, the common floating diffusion region CFD1 or CFD2 may be shared by at least four pixel regions PR1 to PR4. The first portions P1 of the PD isolation structure PIS may be spaced apart from each other in the first direction D1 with the common floating diffusion region CFD1 or CFD2 interposed therebetween, and the second portions P2 may be spaced apart from each other in the second direction D2 with a common floating diffusion region CFD interposed therebetween. The floating diffusion region FD may be provided in the semiconductor substrate 100 to be adjacent to the first to fourth transfer gate electrodes TG1 to TG4.

The first connecting portion CP1 of the connection conductive pattern ICP may connect the common floating diffusion regions CFD1 and CFD2 of the pixel groups GPX to each other, and the second connecting portion CP2 of the connection conductive pattern ICP may be extended from the first connecting portion CP1 and may be connected to one of the first source/drain regions SD1 in one of the pixel groups GPX.

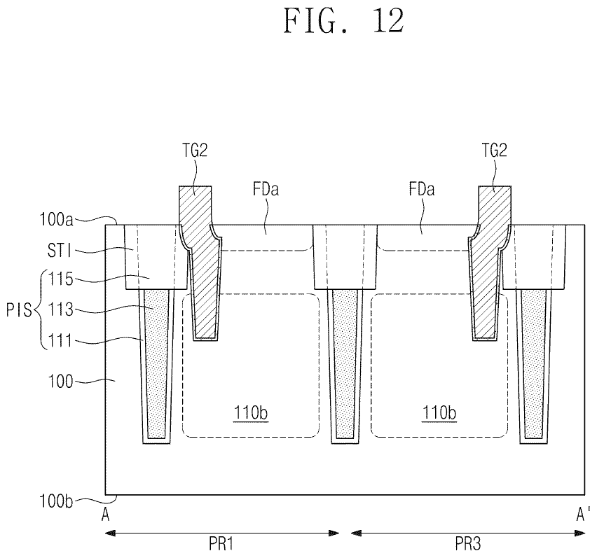

FIGS. 12 to 19 are sectional views, which are taken along the line A-A′ of FIG. 2 to illustrate a method of fabricating an image sensor according to some example embodiments.

Referring to FIGS. 2 and 12, the semiconductor substrate 100 of the first conductivity type (e.g., p-type) may be provided. In some example embodiments, the semiconductor substrate 100 may include an epitaxial layer. The semiconductor substrate 100 may have the first surface 100a and the second surface 100b, which are opposite to each other.

Alternatively, the semiconductor substrate 100 may be or may include a bulk semiconductor substrate, which includes a well of the first conductivity type. In some example embodiments, the semiconductor substrate 100 may be or include a silicon-on-insulator (SOI) substrate, a germanium substrate, a germanium-on-insulator (GOI) substrate, or a silicon-germanium substrate.

In each of the pixel regions PR, the device isolation layer STI may be formed in a portion of the semiconductor substrate 100 adjacent to the first surface 100a to define active portions. The formation of the device isolation layer STI may include pattering the first surface 100a of the semiconductor substrate 100 to form a shallow trench (e.g., a first trench), forming a liner insulating layer to conformally cover an inner surface of the first trench, and forming an insulating layer to fill the first trench provided with the liner insulating layer. The formation of the device isolation layer STI may be formed before or after forming the photoelectric conversion elements 110a and 110b.

The PD isolation structure PIS may be formed in the semiconductor substrate 100 to define the pixel regions PR. The formation of the PD isolation structure PIS may include patterning and etching the first surface 100a of the semiconductor substrate 100 to form a second trench, forming a liner insulating layer to conformally cover an inner surface of the second trench using a process such as but not limited to a chemical vapor deposition (CVD) process, depositing a semiconductor layer to fill the second trench provided with the liner insulating layer, and planarizing the liner insulating layer and the semiconductor layer to expose the first surface 100a of the semiconductor substrate 100 and to form the liner insulating pattern 111, the gapfill pattern 113, and the capping insulating pattern 115 in the second trench using a process such as but not limited to a chemical mechanical planarization (CMP) process and/or an etch-back process.

The second trench may further include extension trenches, which are extended toward the center of each pixel region PR. In each pixel region PR1-PR4, the extension trenches may be extended in the second direction D2 and may be spaced apart from each other in the second direction D2.

In some example embodiments, the liner insulating pattern 111 and the capping insulating pattern 115 may be formed of or include at least one of silicon oxide, silicon nitride, and/or silicon oxynitride. The gapfill pattern 113 may include a doped poly-silicon layer and/or an undoped poly-silicon layer.

Next, the first and second photoelectric conversion elements 110a and 110b may be formed in each of the pixel regions PR1 to PR4.

In each of the pixel regions PR, the first and second photoelectric conversion elements 110a and 110b may be formed by doping portions of the semiconductor substrate 100 with impurities of the second conductivity type (e.g., n-type) different from the first conductivity type. The first and second photoelectric conversion elements 110a and 110b may be spaced apart from the first and second surfaces 100a and 100b of the semiconductor substrate 100. The first and second photoelectric conversion elements 110a and 110b may be formed before or after forming the PD isolation structure PIS.

Next, the first and second transfer gate electrodes TG1 and TG2 may be respectively formed on the first active portions ACT1 in each pixel region PR. The formation of the first and second transfer gate electrodes TG1 and TG2 may include patterning the first surface 100a of the semiconductor substrate 100 to form a gate recess region in each of the pixel regions PR, forming a gate insulating layer to conformally cover an inner surface of the gate recess region, forming a gate conductive layer to fill the gate recess region, and patterning the gate conductive layer. Each of the first and second transfer gate electrodes TG1 and TG2 may include two vertical portions, which are disposed in the semiconductor substrate 100.

A gate insulating layer GIL may include a silicon oxide layer, a silicon oxynitride layer, or a silicon nitride layer. A deposition process may be performed to form the gate insulating layer GIL conformally covering an inner surface of a vertical trench VT.

The first and second transfer gate electrodes TG1 and TG2 may be formed by forming the gate conductive layer to fill the vertical trench VT provided with the gate insulating layer GIL and patterning the gate conductive layer. The gate conductive layer may include a doped poly-silicon layer, a metal silicide layer, a conductive metal nitride layer, or a metal layer.

During the formation of the first and second transfer gate electrodes TG1 and TG2, the gate electrodes RG, SG, and SFG of the pixel transistors may be formed in the second active portions ACT2 in each of the pixel regions PR1 and PR2.

After the formation of the first and second transfer gate electrodes TG1 and TG2, the first doped regions FDa may be formed in portions of the semiconductor substrate 100 at sides of the first and second transfer gate electrodes TG1 and TG2. The first doped regions FDa may be formed by an ion implantation process of injecting impurities of the second conductivity type using an ion injection mask. Furthermore, the source/drain regions (not shown) of the pixel transistors may be formed during the formation of the first doped regions FDa.

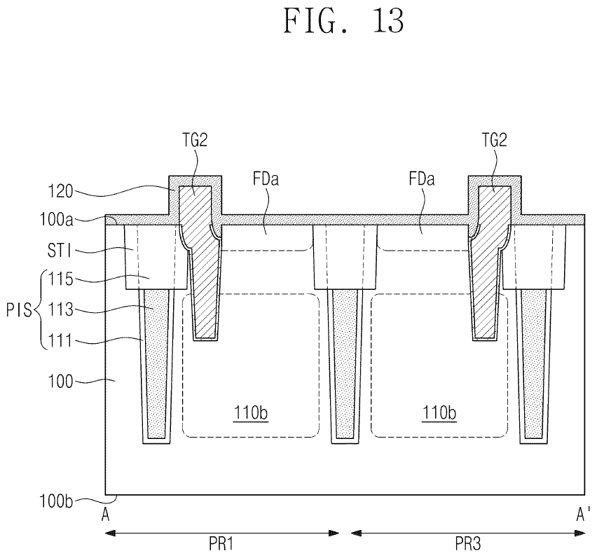

Referring to FIG. 13, a spacer insulating layer 120 may be deposited on the first surface 100a of the semiconductor substrate 100. The spacer insulating layer 120 may cover the first and second transfer gate electrodes TG1 and TG2 and the pixel gate electrodes with a uniform thickness.

The spacer insulating layer 120 may be formed of or include at least one of, for example, silicon oxide, silicon nitride, silicon oxynitride, silicon carbon nitride (SiCN), or silicon carbon oxynitride (SiCON).

The spacer insulating layer 120 may be deposited by, for example, one or more of an atomic layer deposition (ALD) process, a plasma-enhanced chemical vapor deposition (PECVD) process, a low pressure CVD (LPCVD) process, or a flowable CVD (FCVD) process.

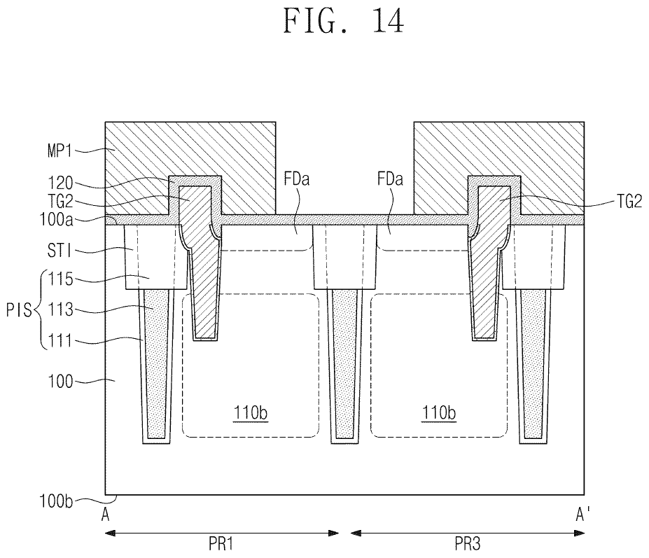

Referring to FIGS. 2 and 14, a first mask pattern MP1, which has an opening exposing a region where a connection conductive pattern will be formed, may be formed on the spacer insulating layer 120.

In each of the pixel regions PR1 to PR4, the opening of the first mask pattern MP1 may be overlapped with portions of the first doped regions FDa and a portion of one of the first source/drain regions SD1 of the pixel transistors.

In some example embodiments, the first mask pattern MP1 may be formed by coating the first surface 100a of the semiconductor substrate 100 with a photoresist layer and performing exposing and developing steps on the photoresist layer.

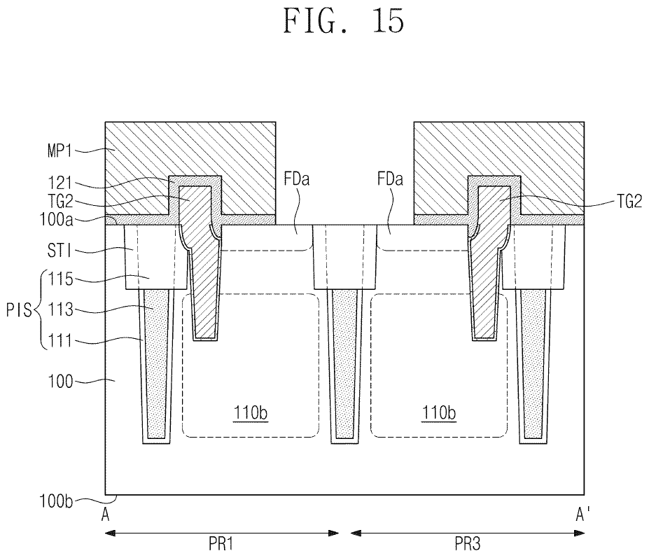

Referring to FIGS. 2 and 15, a spacer insulating pattern 121 may be formed by anisotropically etching the spacer insulating layer 120 using the first mask pattern MP1 as an etch mask.

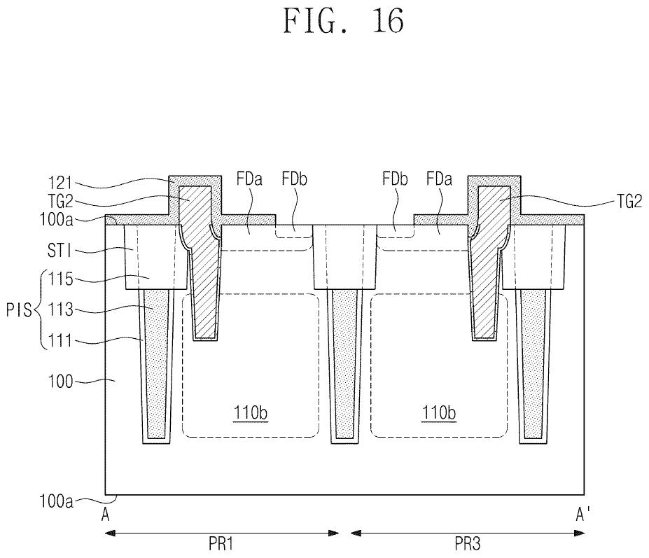

Referring to FIGS. 2 and 16, the second doped regions FDb may be formed in portions of the first doped regions FDa. The second doped regions FDb may be formed through an ion implantation process of injecting impurities of the second conductivity type using the spacer insulating pattern 121 as an ion injection mask pattern.

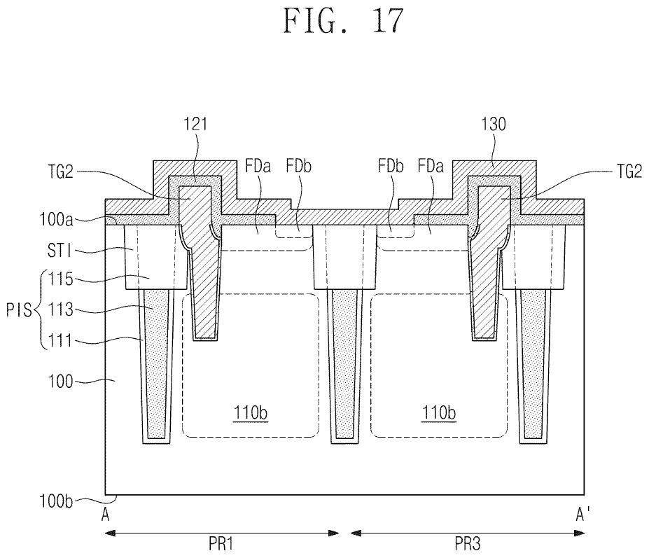

Referring to FIGS. 2 and 17, a conductive layer 130 may be deposited on the semiconductor substrate 100 to have a substantially uniform thickness. The conductive layer 130 may be in direct contact with the second doped regions FDb and may cover the spacer insulating pattern 121.

The conductive layer 130 may include, for example, a doped poly-silicon layer, a metal silicide layer, a conductive metal nitride layer, or a metal layer. For example, the conductive layer 130 may be formed by depositing a semiconductor layer, and in some example embodiments, it may be doped in situ with impurities, during the deposition of the semiconductor layer. A doping concentration of the conductive layer 130 may be lower than, e.g., lower by an order of magnitude or more than, a doping concentration of the second doped regions FDb.

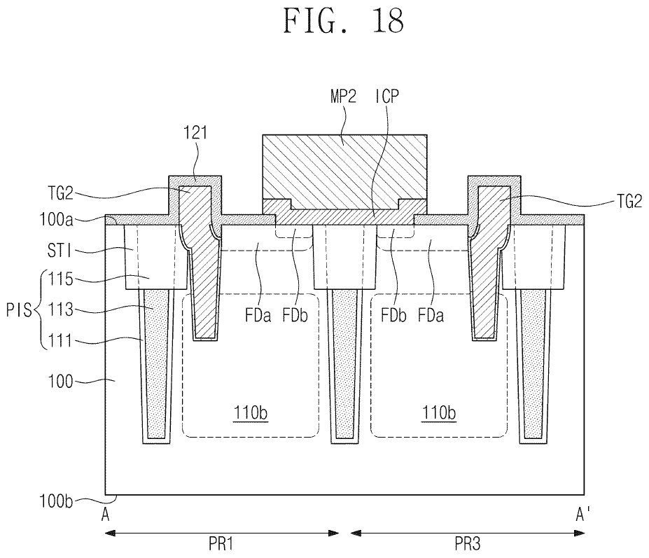

Referring to FIGS. 2 and 18, a second mask pattern MP2 may be formed on the conductive layer 130 and may be overlapped with the first and second floating diffusion regions FD1 and FD2 and one of the first source/drain regions SD1.

Next, the connection conductive pattern ICP may be formed by anisotropically etching the conductive layer 130 using the second mask pattern MP2 as an etch mask. The second mask pattern MP2 may be removed, after the formation of the connection conductive pattern ICP.

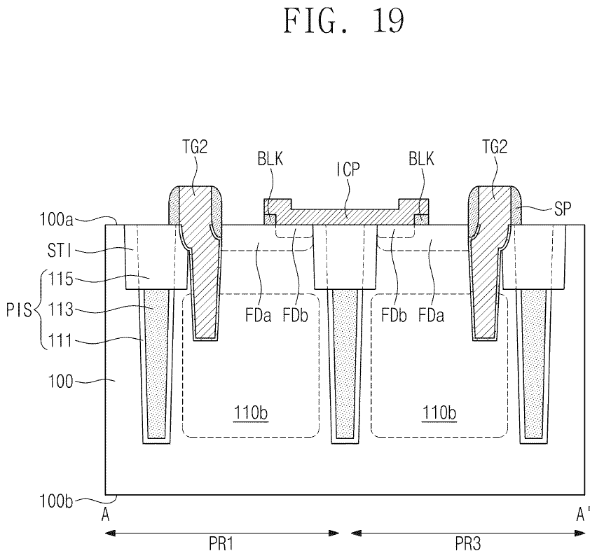

Referring to FIGS. 2 and 19, an etching process (e.g., an etch-back process) may be performed on the spacer insulating pattern 121. As a result, the insulating spacers SP, which are remaining portions of the spacer insulating pattern 121, may be formed on opposite sides surfaces of the first and second transfer gate electrodes TG1 and TG2 and opposite sides surfaces of the pixel gate electrodes PG1 and PG2, and the blocking pattern BLK may be formed below the edge portion EP of the connection conductive pattern ICP.

Next, as shown in FIG. 3A, the first and second etch stop layers 140 and 150 may be sequentially deposited on the first surface 100a of the semiconductor substrate 100 to have a uniform thickness.

The first and second etch stop layers 140 and 150 may be deposited by, for example, one or more of a plasma-enhanced chemical vapor deposition (PECVD) process, a low pressure CVD (LPCVD) process, or a flowable CVD (FCVD) process. The first and second etch stop layers 140 and 150 may be formed of or include silicon nitride or silicon oxynitride.

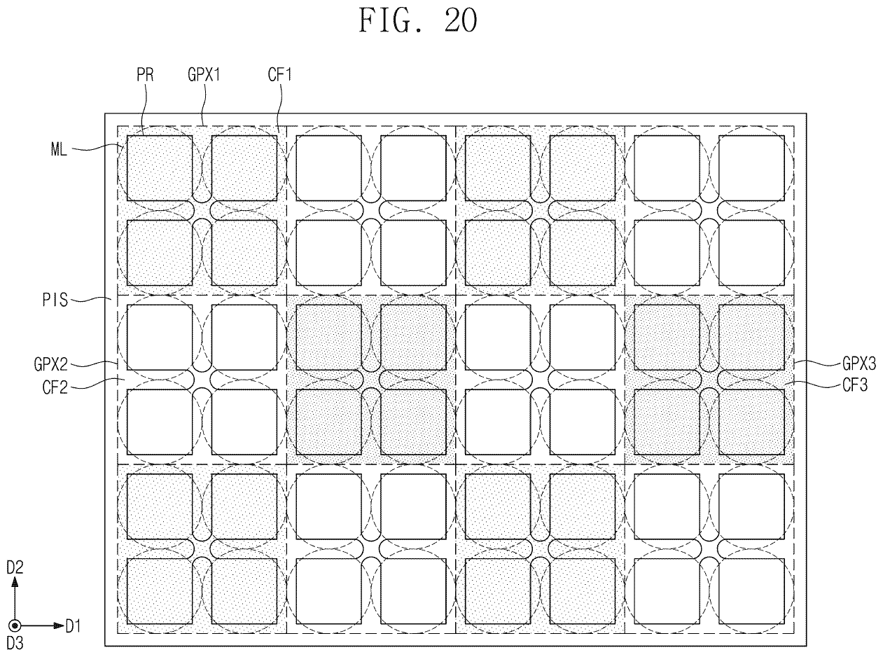

FIG. 20 is a plan view illustrating an image sensor according to some example embodiments.

Referring to FIG. 20, the image sensor may include first to third pixel groups GPX1, GPX2, and GPX3, which are two-dimensionally arranged in the first and second directions D1 and D2. In odd-numbered rows, the first and second pixel groups GPX1 and GPX2 may be alternately and repeatedly arranged. In even-numbered rows, the second and third pixel groups GPX2 and GPX3 may be alternately and repeatedly arranged. Each of the first to third pixel groups GPX1, GPX2, and GPX3 may include the pixel regions PR which are arranged in a 2×2 shape. The PD isolation structure PIS may separate the first to third pixel groups GPX1, GPX2, and GPX3 from each other. When viewed in a plan view, the PD isolation structure PIS may be inserted into each of the pixel groups GPX1, GPX2, and GPX3 to separate the pixel regions PR from each other. However, the PD isolation structure PIS may be cut at the center of each of the pixel groups GPX1, GPX2, and GPX3, and thus, the pixel regions PR, which are included in each pixel group, may be connected to each other. The first pixel group GPX1 may be covered with the first color filter CF1. The second pixel group GPX2 may be covered with the second color filter CF2. The third pixel group GPX3 may be covered with the third color filter CF3. In some example embodiments, the first color filter CF1 may have one of the red, green, and blue colors. The second color filter CF2 may have another of the red, green, and blue colors. The third color filter CF3 may have the remaining color of the red, green, and blue colors. Micro lenses ML may be disposed on the first to third color filters CF1, CF2, and CF3. The micro lenses ML may be placed to correspond to and overlap with the pixel regions PR, respectively. That is, one micro lens ML may be disposed on each pixel PX. The micro lenses ML, which are arranged in a 2×2 shape, may be disposed on each of the pixel groups GPX1, GPX2, and GPX3. Owing to the arrangement of the micro lens ML, it may be possible to increase the light concentration in each of the pixel regions PR and thereby to realize a clear image.

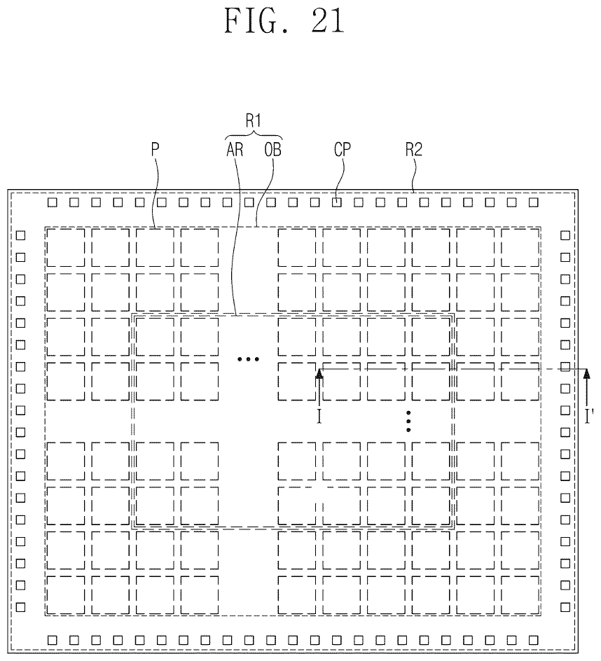

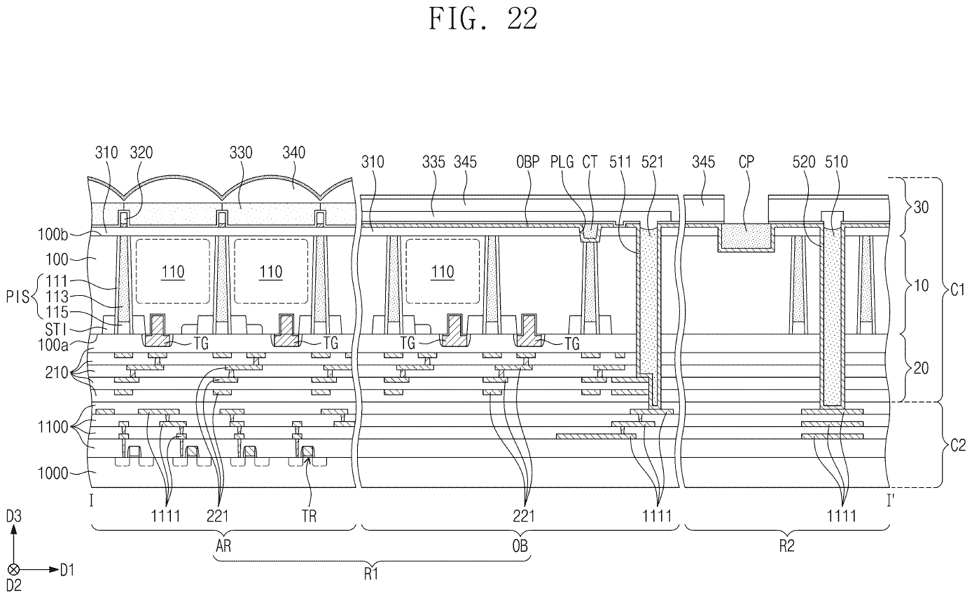

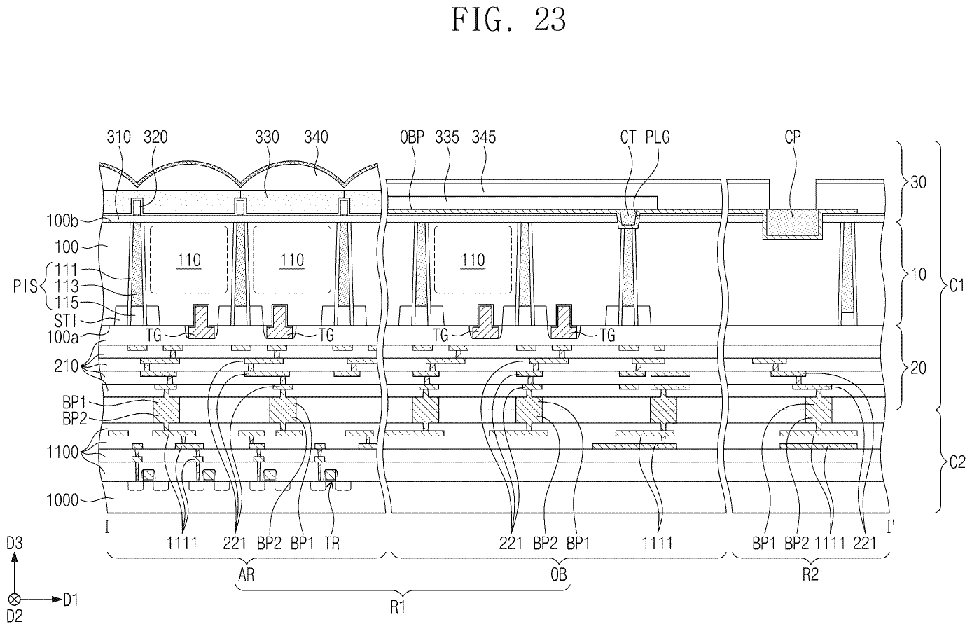

FIG. 21 is a plan view schematically illustrating an image sensor including a semiconductor device according to some example embodiments. FIGS. 22 and 23 are sectional views, which are taken along a line I-I′ of FIG. 21 to illustrate an image sensor according to some example embodiments.

Referring to FIGS. 21 and 22, the image sensor may include a sensor chip C1 and a logic chip C2. The sensor chip C1 may include a pixel array region R1 and a pad region R2.

The pixel array region R1 may include a plurality of unit pixels P, which are two-dimensionally arranged in two different directions (e.g., in the first and second directions D1 and D2). Each of the unit pixels P may include a photoelectric conversion device and readout devices. An electrical signal, which is generated by an incident light, may be output from each of the unit pixels P of the pixel array region R1.

The pixel array region R1 may include a light-receiving region AR and a light-blocking region OB. When viewed in a plan view, the light-blocking region OB may be provided to enclose the light-receiving region AR. For example, the light-blocking region OB may be provided to enclose the light-receiving region AR in four different directions (e.g., up, down, left, and rights directions), when viewed in a plan view. In some example embodiments, reference pixels P, to which light is not incident, may be provided in the light-blocking region OB, and in this case, by comparing a charge amount, which is obtained from the unit pixel P in the light-receiving region AR, with an amount of charges generated in the reference pixels P, it may be possible to calculate a magnitude of an electrical signal generated by the unit pixel P.

A plurality of conductive pads CP, which are used to input or output control signals and photoelectric signals, may be disposed in the pad region R2. The pad region R2 may be provided to enclose the pixel array region R1, when viewed in a plan view, and in this case, the image sensor may be easily connected to an external device. The conductive pads CP may be used to transmit electrical signals, which are generated in the unit pixels P, to an external device.

The sensor chip C1 may be provided to have the same features as the light-receiving region AR of the image sensor described above. In other words, the sensor chip C1 may include the photoelectric conversion circuit layer 10, which is provided between the pixel circuit layer 20 and the optically-transparent layer 30 in a vertical direction, as described above. The photoelectric conversion circuit layer 10 of the sensor chip C1 may include the semiconductor substrate 100, the PD isolation structure PIS defining the pixel regions, and photoelectric conversion elements 110 provided in the pixel regions, as described above. The PD isolation structure PIS may have substantially the same structure, on the light-receiving region AR and the light-blocking region OB. The PD isolation structure PIS may be disposed in the semiconductor substrate 100 of the light-blocking region OB. The gapfill pattern 113 of the PD isolation structure PIS may be electrically connected to a back-side contact plug PLG, in the light-blocking region OB. A predetermined bias may be applied to the gapfill pattern 113 through the back-side contact plug PLG. The back-side contact plug PLG may have a width that is larger than the PD isolation structure PIS. The back-side contact plug PLG may be formed of or include at least one of metallic materials and/or metal nitride materials. For example, the back-side contact plug PLG may be formed of or include at least one of titanium and/or titanium nitride.

A contact pattern CT may be buried in a contact hole, in which the back-side contact plug PLG is formed. The contact pattern CT may include a material that is different from the back-side contact plug PLG. For example, the contact pattern CT may be formed of or include aluminum (Al).

The contact pattern CT and the back-side contact plug PLG may be electrically connected to the gapfill pattern 113 of the PD isolation structure PIS. A positive bias may be applied to the gapfill pattern 113 of the PD isolation structure PIS through the contact pattern CT, and in this case, the positive bias may be supplied from the light-blocking region OB to the light-receiving region AR. Thus, it may be possible to reduce a dark current at an interface between the PD isolation structure PIS and the semiconductor substrate 100.

The optically-transparent layer 30 may include a light-blocking pattern OBP, a filtering layer 335, and an organic layer 345, in the light-blocking region OB. In some example embodiments, the PD isolation structure PIS may be continuously extended from the light-receiving region AR to the light-blocking region OB.

In the light-blocking region OB, the light-blocking pattern OBP may be disposed on a top surface of the planarization insulating layer 310. The light-blocking pattern OBP may include the same material as the conductive pattern of the grid structure 320 in the light-receiving region AR. In other words, the light-blocking pattern OBP may include a metal pattern and a metal oxide pattern. For example, the light-blocking pattern OBP may be formed of or include at least one of titanium nitride or titanium oxynitride. The light-blocking pattern OBP may not be extended to the light-receiving region AR.

The light-blocking pattern OBP may prevent light from being incident into the photoelectric conversion elements PD, which are provided in the light-blocking region OB. The photoelectric conversion elements PD in the reference pixel regions of the light-blocking region OB may be configured to output a noise signal, not a photoelectric signal. The noise signal may be produced by electrons, which are generated by heat or a dark current.

The filtering layer 335 may cover the light-blocking pattern OBP in the light-blocking region OB. The filtering layer 335 may block light of a wavelength different from the color filters 330. For example, the filtering layer 335 may block infrared light. The filtering layer 335 may include a blue color filter, but example embodiments are not limited thereto.

The organic layer 345 and a passivation layer may be provided on the filtering layer 335 in the light-blocking region OB and the pad region R2. The organic layer 345 may be formed of or include the same material as the micro lenses 340.

A first penetration conductive pattern 511 may be provided in the light-blocking region OB to penetrate the semiconductor substrate 100 and may be electrically connected to a metal line of the pixel circuit layer 20 and an interconnection structure 1111 of the logic chip C2. The first penetration conductive pattern 511 may have a first bottom surface and a second bottom surface, which are located at different levels. A first gapfill pattern 521 may be provided in the first penetration conductive pattern 511. The first gapfill pattern 521 may be formed of or include a low-refractive material and may exhibit an insulating property.

In the pad region R2, the conductive pads CP may be provided on the second surface 100b of the semiconductor substrate 100. The conductive pads CP may be buried in the semiconductor substrate 100 and near the second surface 100b. In some example embodiments, the conductive pads CP may be provided in pad trenches, which are formed in the second surface 100b of the semiconductor substrate 100 and in the pad region R2. The conductive pads CP may be formed of or include at least one of metallic materials (e.g., one or more of aluminum, copper, tungsten, titanium, tantalum, or alloys thereof). In a process of mounting an image sensor, bonding wires may be bonded to the conductive pads CP. The conductive pads CP may be electrically connected to an external device through the bonding wires.

A second penetration conductive pattern 520 may be provided in the pad region R2 to penetrate the semiconductor substrate 100 and may be electrically connected to the interconnection structure 1111 of the logic chip C2. The second penetration conductive pattern 520 may be extended to a region on the second surface 100b of the semiconductor substrate 100 and may be electrically connected to the conductive pads CP. A portion of the second penetration conductive pattern 520 may cover bottom and side surfaces of the conductive pads CP. A second gapfill pattern 510 may be provided in the second penetration conductive pattern 520. The second gapfill pattern 510 may include a low-refractive material and may have an insulating property. In the pad region R2, the PD isolation structures PIS may be provided around the second penetration conductive pattern 520.

The logic chip C2 may include a logic semiconductor substrate 1000, logic circuits TR, the interconnection structures 1111 connected to the logic circuits TR, and logic interlayer insulating layers 1100. The uppermost one of the logic interlayer insulating layers 1100 may be bonded to the pixel circuit layer 20 of the sensor chip C1. The logic chip C2 may be electrically connected to the sensor chip C1 through the first and second penetration conductive patterns 511 and 520.

In some example embodiments, the sensor and logic chips C1 and C2 are described to be electrically connected to each other through the first and second penetration conductive patterns 511 and 520, but example embodiments are not limited thereto.

In the embodiment of FIG. 23, the first and second penetration conductive patterns of FIG. 22 may be omitted, and the sensor and logic chips C1 and C2 may be electrically connected to each other through the bonding pads, which are respectively provided in the uppermost metal layers of the sensor and logic chips C1 and C2 and are directly bonded to each other.

In detail, the gapfill pattern 113 of the PD isolation structure PIS, which is extended from the light-receiving region AR to the light-blocking region OB in the sensor chip C1, may be connected to the back-side contact plug PLG, in the light-blocking region OB.

Furthermore, the sensor chip C1 may include first bonding pads BP1, which are provided in the uppermost metal layer of the pixel circuit layer 20, and the logic chip C2 may include second bonding pads BP2, which are provided in the uppermost metal layer of the interconnection structure 1111. The first and second bonding pads BP1 and BP2 may be formed of or include at least one of, for example, tungsten W, aluminum (Al), copper (Cu), tungsten nitride (WN), tantalum nitride (TaN), or titanium nitride (TiN).

The first bonding pads BP1 of the sensor chip C1 and the second bonding pads BP2 of the logic chip C2 may be electrically and directly connected to each other by a hybrid bonding method. The hybrid bonding structure may mean a bonding structure, in which two materials of the same kind are fused at an interface therebetween. For example, in the case where the first and second bonding pads BP1 and BP2 are formed of copper (Cu), they may be physically and electrically connected to each other in a Cu—Cu bonding manner. In addition, insulating layers of the sensor and logic chips C1 and C22 may be bonded to each other in a dielectric-dielectric bonding manner.

According to some example embodiments, by forming a connection conductive pattern connecting floating diffusion regions from each other, it may be possible to prevent or reduce the likelihood of and/or impact from an increase of capacitance and a delay of signals, which may occur when a metal layer is used for the connection, and to improve a conversion gain in in a unit pixel. Alternatively or additionally, it may be possible to increase a degree of freedom of constructing an interconnection structure of the image sensor.

Alternatively or additionally, by placing a blocking pattern between the connection conductive pattern and an active pattern adjacent thereto, it may be possible to prevent or reduce the likelihood of and/or the impact from an electric connection between the connection conductive pattern and the active pattern, which are adjacent to each other.

While some example embodiments have been particularly shown and described, it will be understood by one of ordinary skill in the art that variations in form and detail may be made therein without departing from the spirit and scope of the attached claims. Additionally, example embodiments are not necessarily mutually exclusive with one another. For example, some example embodiments may include one or more features described with reference to one or more figures, and may also include one or more other features described with reference to one or more other figures.

What is claimed is:

1. An image sensor, comprising:
a semiconductor substrate;
an isolation structure in the semiconductor substrate and defining a first pixel region and a second pixel region;
a transfer gate electrode on the first pixel region;
a floating diffusion region in the first pixel region and at a side of the transfer gate electrode;
a pixel gate electrode on the second pixel region;
a source/drain region in the second pixel region and at a side of the pixel gate electrode;
a connection conductive pattern on a first surface of the semiconductor substrate to connect the floating diffusion region to the source/drain region, the connection conductive pattern comprising an edge portion adjacent to an outer side surface of the connection conductive pattern; and
a blocking pattern between the edge portion of the connection conductive pattern and the first surface of the semiconductor substrate.

2. The image sensor of claim 1, wherein the blocking pattern at least partly overlaps with the edge portion of the connection conductive pattern, when viewed in a plan view.

3. The image sensor of claim 1, wherein an inner side surface of the blocking pattern contacts a portion of the connection conductive pattern.

4. The image sensor of claim 1, further comprising:
a device isolation layer defining an active portion, in each of the first and second pixel regions,
wherein the blocking pattern comprises a first portion on the active portion and a second portion on the device isolation layer.

5. The image sensor of claim 1, wherein
the connection conductive pattern comprises a pad portion in contact with the floating diffusion region and the source/drain region, and
a bottom surface of the pad portion is placed at a level lower than a bottom surface of the blocking pattern.

6. The image sensor of claim 1, wherein
the connection conductive pattern comprises a pad portion contacting the floating diffusion region and the source/drain region, and
a top surface of the edge portion is at a level higher than a top surface of the pad portion.

7. The image sensor of claim 1, wherein
the floating diffusion region, the source/drain region, and the connection conductive pattern contain dopants of a first conductivity type, and
a concentration of the dopants in the connection conductive pattern is lower than a concentration of the dopants in the floating diffusion region.

8. The image sensor of claim 1, wherein
the connection conductive pattern comprises a pad portion contacting the floating diffusion region and the source/drain region, and
a thickness of the pad portion is smaller than a thickness of the pixel gate electrode.

9. The image sensor of claim 1, further comprising:
insulating spacers at a first side of the transfer gate electrode, a second side of the transfer gate electrode, a first side of the pixel gate electrode, and a second side of the pixel gate electrode,
wherein the blocking pattern comprises a same insulating material as the insulating spacers.

10. The image sensor of claim 1, wherein
the floating diffusion region comprises a first doped region and a second doped region in the first doped region,
a doping concentration of the second doped region is higher than a doping concentration of the first doped region, and
the connection conductive pattern contacts the second doped region of the floating diffusion region.

11. The image sensor of claim 1, further comprising:
an etch stop layer covering the transfer gate electrode and the pixel gate electrode,
wherein a portion of the etch stop layer covers an outer side surface of the blocking pattern and an outer side surface of the connection conductive pattern with a uniform thickness.

12. The image sensor of claim 1, further comprising:
a first photoelectric conversion element and a second photoelectric conversion element in each of the first and second pixel regions and in the semiconductor substrate,
wherein the transfer gate electrode comprises a first transfer gate electrode and a second transfer gate electrode, in each of the first and second pixel regions,
the floating diffusion region comprises a first floating diffusion region and a second floating diffusion region, in each of the first and second pixel regions,
the first transfer gate electrode is between the first photoelectric conversion element and the first floating diffusion region, and
the second transfer gate electrode is between the second photoelectric conversion element and the second floating diffusion region.

13. An image sensor, comprising:
a semiconductor substrate;
an isolation structure in the semiconductor substrate and defining a first pixel region and a second pixel region;
a plurality of photoelectric conversion elements in the first pixel region and the second pixel region, respectively;
a first transfer gate electrode in the first pixel region and in a first floating diffusion region at a side of the first transfer gate electrode;
a second transfer gate electrode in the second pixel region and in a second floating diffusion region at a side of the second transfer gate electrode;
a plurality of pixel gate electrodes respectively provided in the first and second pixel regions, and source/drain regions provided at first sides and second sides of each of the pixel gate electrodes;
a connection conductive pattern connecting the first and second floating diffusion regions to a first source/drain region, which is one of the source/drain regions, the connection conductive pattern comprising a first connecting portion contacting the first and second floating diffusion regions, and a second connecting portion extending from the first connecting portion and contacting the first source/drain region; and
a blocking pattern between a bottom surface of an edge portion of the connection conductive pattern and a first surface of the semiconductor substrate.

14. The image sensor of claim 13, wherein an outer side surface of the connection conductive pattern is vertically aligned to an outer side surface of the blocking pattern.

15. The image sensor of claim 13, wherein a portion of the connection conductive pattern has a bottom surface at a level lower than a bottom surface of the blocking pattern.

16. The image sensor of claim 13, wherein a smallest width of the first connecting portion is larger than a smallest width of the second connecting portion.

17. The image sensor of claim 13, further comprising:
a device isolation layer defining a first active portion and a second active portion, in each of the first and second pixel regions,
the first and second floating diffusion regions are respectively arranged in the first active portions of the first and second pixel regions, and
the source/drain regions are respectively arranged in the second active portions of the first and second pixel regions.

18. The image sensor of claim 13, wherein
the first and second floating diffusion regions and the connection conductive pattern comprise dopants of a first conductivity type, and
a concentration of the dopants in the connection conductive pattern is lower than a concentration of the dopants in the first and second floating diffusion regions.

19. An image sensor, comprising:
a semiconductor substrate having a first surface and a second surface, which are opposite to each other;
an isolation structure in the semiconductor substrate to define first to fourth pixel regions;
a plurality of photoelectric conversion elements in the first to fourth pixel regions and in the semiconductor substrate;
a device isolation layer adjacent to the first surface of the semiconductor substrate and defining a first active portion and a second active portion in each of the first to fourth pixel regions;
a plurality of transfer gate electrodes on the first active portions in the first to fourth pixel regions;
a plurality of floating diffusion regions in the first active portions in the first to fourth pixel regions;
a plurality pixel transistors on the second active portions in the first to fourth pixel regions;
a connection conductive pattern on the first surface of the semiconductor substrate and connecting a one of the plurality of floating diffusion regions in the first to fourth pixel regions to a first source/drain region of one of the pixel transistors, the connection conductive pattern comprising an edge portion adjacent to an outer side surface thereof, and a pad portion contacting the one of the plurality of floating diffusion regions and the first source/drain region;
a blocking pattern between the edge portion of the connection conductive pattern and the first surface of the semiconductor substrate;
a plurality of color filters on the second surface of the semiconductor substrate to correspond to the first to fourth pixel regions;
a grid structure between the color filters and at least partially overlapping the isolation structure; and
a plurality of micro lenses on the plurality of color filters.

20. The image sensor of claim 19, wherein a thickness of the pad portion of the connection conductive pattern is smaller than a thickness of pixel gate electrodes of the pixel transistors.
